(19) United States
(12) Patent Application Publication
(10) Pub. No.: US 2005/0169488 A1
(43) Pub. Date: Aug. 4, 2005

(54) Acoustic characteristic adjustment device

(76) Inventors: Shinjiro Kato, Saitama-ken (JP); Akira Shimizu, Saitama-ken (JP); Moriyuki Oshima, Saitama-ken (JP); Mitsuo Nakazato, Saitama-ken (JP); Shigeki Kobayashi, Saitama-ken (JP); Kunio Toyoda, Tokyo (JP); Koji Takano, Tokyo (JP); Shokichiro Hino, Tokyo (JP); Tomohiko Endo, Tokyo (JP); Kouichi Tsuchiya, Tokyo (JP)

Correspondence Address: ARENT FOX PLLC, 1050 CONNECTICUT AVENUE, N.W., SUITE 400, WASHINGTON, DC, 20036, US

(21) Appl. No.: 11/024,770

(22) Filed: Dec. 30, 2004

(30) Foreign Application Priority Data
Nov. 18, 2004 (JP) 2004-334906
Jan. 6, 2004 (JP) 2004-1224

(51) Int. Cl. H03G 5/00; H03G 3/00

(52) U.S. Cl. 381/98; 381/94.3; 381/97

(57) ABSTRACT

An improved acoustic characteristic adjustment device comprises signal processing units including high frequency convolution arithmetic sections, low frequency convolution arithmetic sections, and delay sections. The device further comprises: an operation section from which a listener inputs a target characteristic in order to adjust a desired acoustic characteristic; an impulse characteristic control section; and a delay time control section. The impulse characteristic control section calculates impulse response data to effect convolution arithmetics. The delay time control section calculates alignment delay times necessary for sounds emitted from the speakers to reach a listening position. The delay time control section also calculates correction times for compensating various phase deviations. Times obtained by correcting the alignment delay times with the correction times are set as the delay times of the delay sections, respectively.

### BACKGROUND OF THE INVENTION

The present invention relates to an acoustic characteristic adjustment device, which adjusts acoustic characteristics in a listening position or the like to desired ones.

The present application claims priority from Japanese Applications Nos. 2004-1224 and 2004-334906, the disclosures of which are incorporated herein by reference.

In a multichannel speaker system, which divides an audio signal in an audible frequency band into a plurality of frequency bands and operates each of a plurality of speakers, a linear phase filter is used. The linear phase filter has a frequency division characteristic and a linear phase (constant delay time) characteristic.

In a multichannel speaker system disclosed in Japanese Unexamined Patent Application Publication No. Hei 4-313996, as shown in FIG. 1 of the publication, linear phase filters 4₁, 4₂, . . . 4ₙ are provided to divide an audio signal from a signal source into a plurality of frequency bands. Delay processing circuit sections 8₁, 8₂, . . . 8ₙ appropriately delay respective audio signals divided by the linear phase filters 4₁, 4₂, . . . 4ₙ and provide them to respective speakers 3₁, 3₂, . . . 3ₙ. Thus, propagation delay time t₁, t₂, . . . tₙ is adjusted in such a manner as to align total delay time with a total phase in a listening position (the position of a microphone 20) of sound emitted from each speaker 3₁, 3₂, . . . 3ₙ.

In the foregoing conventional multichannel speaker system, however, only the linear phase filters 4₁, 4₂, . . . 4ₙ divide the audio signal into the plurality of frequency bands. Thus, the audio signal divided into each frequency band is output after being necessarily delayed by the linear phase filter 4₁, 4₂, . . . 4ₙ by a predetermined time, because of the characteristics (constant delay time) of the linear phase filter.

There is the so-called audiovisual equipment (AV equipment), which reproduces a storage medium corresponding to multimedia such as, for example, a CD (compact disc) and a DVD (digital versatile disc) for storing not only audio signals (audio information) but also image information and the like, and outputs the image information and the audio information to a display and a plurality of speakers for reproduction. Taking a case where the foregoing conventional multichannel speaker system is applied to the audiovisual equipment, reproduced sound is always emitted with delay with respect to images shown in the display, even if the foregoing delay processing circuit sections 8₁, 8₂, . . . 8ₙ adjust delay time. Therefore, there is a problem that timing mismatch occurs between the motion of the images and sound.

In other words, if the linear phase filters are applied to the speaker system, there are advantages that swell in an amplitude characteristic due to phase interference between the divided frequency bands does not occur, and the total phases are aligned if a frequency characteristic between channels is changed to correct a sound transfer characteristic with respect to an audience in a position asymmetrical with speakers. On the other hand, there is the problem that the timing mismatch occurs between the images reproduced on the display and the sound from the speakers, when the image and sound information recorded on the foregoing storage medium or the like is reproduced for the sake of the so-called simultaneous reproduction.

To be more specific, when the storage medium, on which a movie is recorded, is reproduced to reproduce images and sound of the movie on the display and speakers, there is a problem that timing mismatch occurs between the motion of a mouth of a person in the image and the sound (utter line) of the person.

### SUMMARY OF THE INVENTION

The present invention was devised in order to solve the foregoing problem, and an object of the present invention is to provide an acoustic characteristic adjustment device which is properly applied to not only audio equipment, which can allow a certain degree of delay, but also AV equipment. When audio information, image information, and the like are reproduced on speakers, a display, and the like, a listener (or audience) can flexibly adjust acoustic characteristics in a listening position (or watching position) in order to prevent the foregoing mismatch.

Another object of the present invention is to provide an acoustic characteristic adjustment device in which a listener or the like can flexibly adjust acoustic characteristics in a listening position or the like in accordance with an intended purpose and the like.

Further another object of the present invention is to provide an acoustic characteristic adjustment device which has at least a channel divider function, a graphic equalizer function, and a time alignment function as the function of adjusting acoustic characteristics.

Further another object of the present invention is to provide an acoustic characteristic adjustment device which adjusts acoustic characteristics by digital signal processing, and reduces the amount of data required for the digital signal processing.

An acoustic characteristic adjustment device according to a first aspect of the present invention comprises signal processing means, operation means, impulse characteristic control means, and delay time control means. The signal processing means, which is provided in each of one or a plurality of channels, adjusts the acoustic characteristic of sound emitted from a speaker of each channel in a listening position or the like. The signal processing means of each channel comprises convolution arithmetic means, and delay means. The convolution arithmetic means carries out frequency division and the adjustment of gain and phase characteristic with respect to a signal component of an input audio signal in one or a plurality of frequency bands, by convolution arithmetic. The delay means delays an output signal from the convolution arithmetic means, and outputs the output signal to the speaker. Target characteristic, which at least represents the characteristic of the one or plurality of frequency bands of each channel, the gain and phase characteristic, and a distance from each speaker to the listening position or the like, are selectively input from the operation means. The impulse characteristic control means generates impulse response data of the one or plurality of frequency bands of each channel, on the basis of the target characteristic input from the operation means. The impulse characteristic data represents an impulse response which is used for the convolution arithmetic with the input audio signal in the convolution arithmetic means. The delay time control means calculates each alignment time which sound needs for traveling each distance, and a correction time for compensating difference in output time output from the convolution arithmetic means. The delay time control means also calculates delay time by correcting each alignment time with the correction time, and adjusts the delay time of the delay means with the calculated delay time.

According to a second aspect of the present invention, in the acoustic characteristic adjustment device in accordance with the first aspect, the number of taps of the convolution arithmetic means is reduced with increase in frequency of the one or plurality of frequency bands.

According to a third aspect of the present invention, in the acoustic characteristic adjustment device in accordance with the first or second aspect, the operation means comprises input means. At least the target characteristic of the one or plurality of frequency bands of each channel is variably set from the input means.

According to a fourth aspect of the present invention, in the acoustic characteristic adjustment device in accordance with any one of the first to third aspects, the operation means comprises input means. At least the type of filter which is realized in the convolution arithmetic means of each channel by the convolution arithmetic is integrally or separately input from the input means. The impulse characteristic control means generates at least the impulse response data, which represents the impulse response of the convolution arithmetic means of each channel, on the basis of the characteristic of the input type of filter and the target characteristic. The delay time control means calculates the correction time, in accordance with at least the difference in output time according to the characteristic of each filter realized by the convolution arithmetic means of each channel.

According to a fifth aspect of the present invention, in the acoustic characteristic adjustment device in accordance with any one of the first to fourth aspects, the operation means comprises input means. At least the type of filter realized in the convolution arithmetic means of each channel by the convolution arithmetic is integrally or incrementally input and changed from the input means, while at least the variable setup of the target characteristic of the one or plurality of frequency bands of every channel is maintained. The impulse characteristic control means generates at least the impulse response data, which represents the impulse response of the convolution arithmetic means of each channel, on the basis of the characteristic of the changed and input type of filter and target characteristic. The delay time control means calculates the correction time, in accordance with at least the difference in output time according to the characteristic of each filter realized by the convolution arithmetic means of each channel.

According to a sixth aspect of the present invention, the acoustic characteristic adjustment device in accordance with the fourth or fifth aspect further comprises storage means. The storage means stores at least the characteristic of a linear phase filter and the characteristic of a minimum phase filter in advance, as the characteristic of the input type of filter.

According to a seventh aspect of the present invention, in the acoustic characteristic adjustment device in accordance with the sixth aspect, each of the characteristic of the linear phase filter and the characteristic of the minimum phase filter is composed of the data of a frequency spectrum.

According to an eighth of the present invention, in the acoustic characteristic adjustment device in accordance with any one of the fourth to seventh aspects, the impulse characteristic control means comprises target characteristic decision means and inverse Fourier transform arithmetic means. The target characteristic decision means edits the data of the frequency spectrum corresponding to the type of filter input from the operation means, on the basis of the target characteristic. The inverse Fourier transform arithmetic means performs an inverse Fourier transform on the data of the frequency spectrum edited by the target characteristic decision means, to calculate the impulse response data.

According to a ninth aspect of the present invention, in the acoustic characteristic adjustment device in accordance with any one of the fourth to eighth aspects, the impulse characteristic control means comprises inverse Fourier transform arithmetic means and window function arithmetic means. The inverse Fourier transform arithmetic means performs an inverse Fourier transform on the data of the frequency spectrum edited by the target characteristic decision means. The window function arithmetic means calculates a window function on the output of the inverse Fourier transform arithmetic means, to generate the impulse response data.

### BRIEF DESCRIPTION OF THE DRAWINGS

These and other objects and advantages of the present invention will become clear from the following description with reference to the accompanying drawings, wherein:

FIG. 1 is a block diagram showing the configuration of an acoustic characteristic adjustment device according to a best mode for carrying out the invention;

FIGS. 2A to 2G are schematic charts for explaining the impulse responses, gains, phase characteristics, and the like of a linear phase filter and a minimum phase filter;

FIGS. 3A to 3E are schematic diagrams for explaining the input and output characteristics of the linear phase filter and the minimum phase filter;

FIG. 4 is a block diagram showing the configuration of an acoustic characteristic adjustment device according to an embodiment;

FIGS. 5A and 5B are diagrams showing the configuration of the high frequency convolution arithmetic sections and the low frequency convolution arithmetic sections formed in the acoustic characteristic adjustment device shown in FIG. 4;

FIGS. 6A to 6D are diagrams showing the configuration of the operation section provided on the acoustic characteristic adjustment device shown in FIG. 4, and display examples to appear on the display section during adjustment inputs on a channel divider, a graphic equalizer, and time alignment; and

FIGS. 7A to 7C are flowcharts for explaining the operation of the acoustic characteristic adjustment device shown in FIG. 4.

### DETAILED DESCRIPTION OF THE PREFERRED EMBODIMENTS

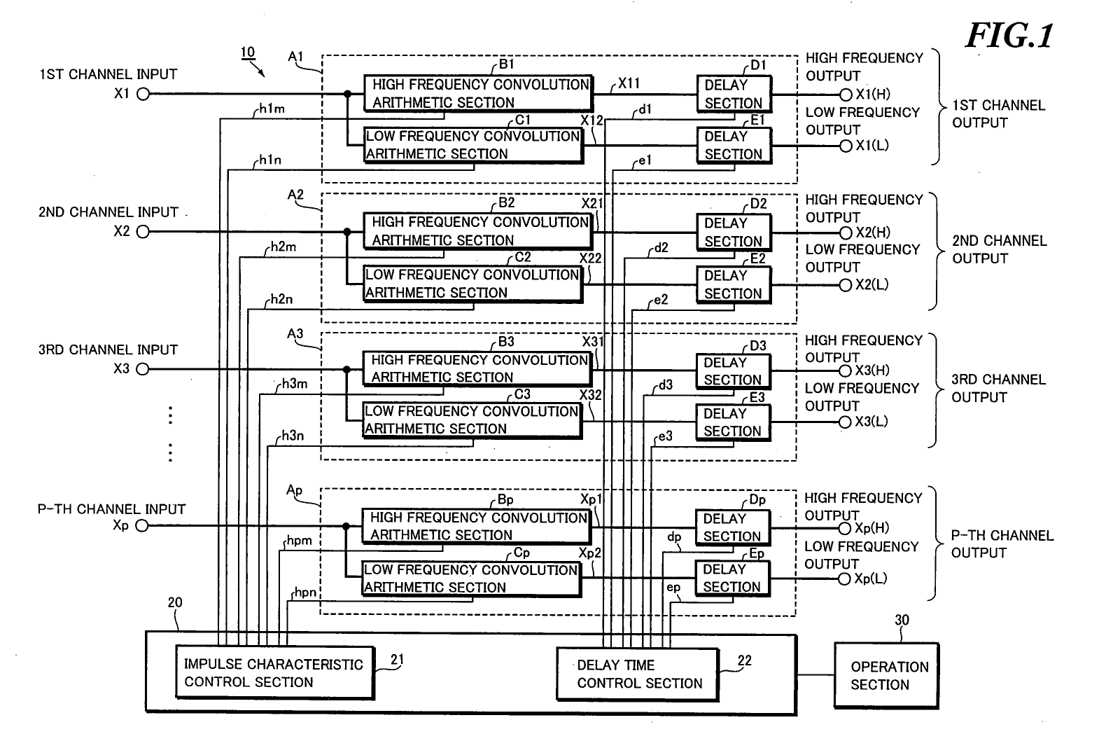

A preferred embodiment of the present invention will be hereinafter described with reference to FIGS. 1 to 3.

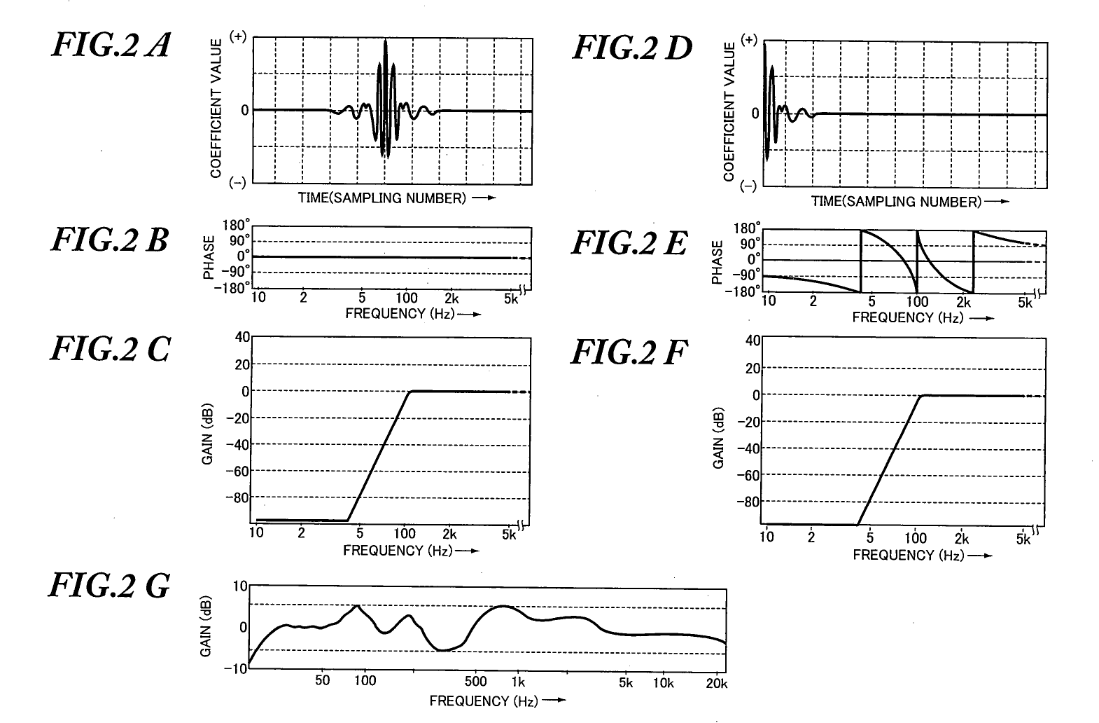

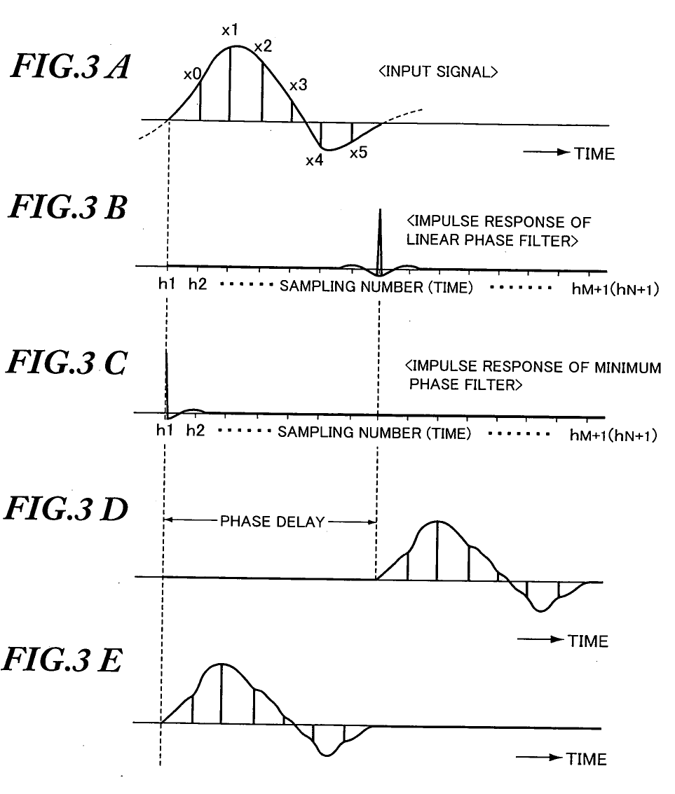

FIG. 1 is a block diagram showing the configuration of an acoustic characteristic adjustment device 10 according to this embodiment. FIGS. 2A to 2G are graphs which schematically show the impulse response, gain, phase characteristics, and the like of a linear phase filter and a minimum phase filter. FIGS. 3A to 3E are graphs which schematically show the input and output characteristics of the linear phase filter and the minimum phase filter.

Referring to FIG. 1, the acoustic characteristic adjustment device 10 comprises p-lines (“p” is a natural number of 1, 2 or more, hereinafter called “p-channels”) of digital signal processing units A1 to Ap.

In this embodiment, by way of example, will be described the configuration of the acoustic characteristic adjustment device 10, in which each of the digital signal processing units A1 to Ap adjusts the acoustic characteristics of an input audio signal with respect to signal components in two bands, that is, a high frequency band and a low frequency band. The configuration of this embodiment shows just one of preferred examples, and is not limited to this configuration. For example, the acoustic characteristics of an audio signal in a single frequency band (for example, the whole audio frequency band, a part of an audio frequency band, or the like) may be adjusted. Otherwise, the acoustic characteristics of an audio signal may be adjusted with respect to each of signal components in three or more frequency bands (for example, high, middle, and low frequency bands, and the like).

Each digital signal processing unit A1 to Ap subjects each of p-channels of digital audio signals X1 to Xp supplied from an arbitrary signal source (not shown) to digital signal processing described later. Thus, digital audio signals X1(H) to Xp(H) in the high frequency band and digital audio signals X1(L) to Xp(L) in the low frequency band are output to drive a speaker (not shown) of each channel. The digital signal processing unit A1 to Ap comprises a DSP (digital signal processor) for carrying out digital signal processing in accordance with a predetermined algorithm, a microprocessor (MPU), or a digital circuit.

Receiving supply from various types of signal source, an input end of each signal processing unit A1 to Ap is so connected that the digital audio signal X1 to Xp composed of a sequence of sampled values is input into each signal processing unit A1 to Ap. As the signal source, there are, for example, a reproducing device for reproducing information recorded on a storage medium such as a CD and a DVD, a site in a telecommunication line such as the Internet to distribute music, images, and the like, a broadcasting station of a television broadcast or a radio broadcast, and the like.

An output end of the digital signal processing unit A1 to Ap is connected to a speaker of each channel through a digital-to-analog converter (DAC) and a power amplifier. Thus, each speaker sounds on the basis of the digital audio signals X1(H) to Xp(H) and X1(L) to Xp(L) which have been subjected to the digital signal processing.

Namely, the acoustic characteristic adjustment device 10 has general versatility which can adjust the gain characteristic, phase characteristic, and the like of the p-channels of digital audio signals X1 to Xp supplied from an arbitrary signal source, in order to adjust the acoustic characteristics such as the gain, phase characteristic, and the like of sound which is emitted from the speakers and reaches a listening position (or watching position). The acoustic characteristic adjustment device 10 can compose AV equipment having a multichannel speaker system, which drives, for example, the p-channels of speakers.

To be more specific, when the acoustic characteristic adjustment device 10 is applied to a 5.1 channel (multichannel) speaker system, the acoustic characteristic adjustment device 10 is provided with at least six lines of digital signal processing units A1 to A6 (p=6). The 5.1 channel (multichannel) speaker system sounds a plurality of speakers each of which has a specific frequency characteristic, to reproduce sound with high quality.

When the acoustic characteristic adjustment device 10 is applied to a 4 channel speaker system, the acoustic characteristic adjustment device 10 is provided with at least four lines (p=4) of signal processing units A1 to A4. In the 4 channel speaker system, two channels of speakers are disposed on the right and left with respect to the listening position (or watching position), in other words, four channels of speakers are disposed in total.

Each signal processing unit A1 to Ap, as shown in FIG. 1, comprises a high frequency convolution arithmetic section B1 to Bp, a low frequency convolution arithmetic section C1 to Cp, a delay section D1 to Dp, and a delay section E1 to Ep. The high frequency convolution arithmetic section B1 to Bp and the low frequency convolution arithmetic section C1 to Cp subject the input digital audio signal X1 to Xp to convolution arithmetic described later. The delay section D1 to Dp delays an output signal X11 to Xp1 from the high frequency convolution arithmetic section B1 to Bp, and outputs the foregoing digital audio signal X1(H) to Xp(H). The delay section E1 to Ep delays an output signal X12 to Xp2 from the low frequency convolution arithmetic section C1 to Cp, and outputs the foregoing digital audio signal X1(L) to Xp(L).

To be more specific, first, the signal processing unit A1 comprises the high frequency convolution arithmetic section B1, the low frequency convolution arithmetic section C1, and the delay sections D1 and E1. The high frequency convolution arithmetic section B1 subjects the signal component in the high frequency band to convolution arithmetic processing. The low frequency convolution arithmetic section C1 subjects the signal component in the low frequency band to the convolution arithmetic processing.

In this embodiment, as described above, the signal is subjected to the convolution arithmetic processing in each line after being divided in two bands, that is, the signal component in the high frequency band and that in the low frequency band, but the present invention is not limited thereto. For example, one convolution arithmetic section may be provided to subject a signal component in the whole frequency band of the so-called audio frequency to the convolution arithmetic processing. Otherwise, one convolution arithmetic section may be provided to subject a signal component in a single frequency band of the audio frequency band to the convolution arithmetic processing. Otherwise, the audio frequency band is divided into three or more frequency bands, and three or more convolution arithmetic sections may be provided to subject a signal component in each frequency band to the convolution arithmetic processing. When such one or a plurality of convolution arithmetic sections are provided to subject one or a plurality of signal components to the convolution arithmetic processing, one or a plurality of delay sections corresponding to each convolution arithmetic section are provided.

Referring back to FIG. 1, the digital audio signal X1 is input into the high frequency convolution arithmetic section B1 in synchronization with a sampling period according to a sampling theorem of Nyquist. The high frequency convolution arithmetic section B1 carries out convolution arithmetic on the signal X1 and impulse response data h1m composed of an M+1 coefficient sequence, which is supplied from an impulse characteristic control section 21 as described later. Thus, of the whole frequency band (for example, an audible frequency band 20 Hz to 20 kHz) of the digital audio signal X1, the frequency of a signal component in a high frequency band BH1 is divided. After the gain, phase characteristic, and the like of the divided signal component are adjusted, the divided signal component is output as the output signal X11.

In other words, since the high frequency convolution arithmetic section B1 carries out the foregoing convolution arithmetic on the basis of the impulse response data h1m, the high frequency convolution arithmetic section B1 functions as a high pass digital filter on the digital audio signal X1. Also, filter characteristics such as the high frequency band (pass band) BH1, gain, phase characteristic, and the like are adjusted on the basis of the impulse response data h1m, so that the frequency convolution arithmetic section B1 has a channel divider function for carrying out frequency division on the foregoing high frequency band BH1, and a graphic equalizer function.

Furthermore, the impulse characteristic control section 21 supplies the high frequency convolution arithmetic section B1 with the impulse response data h1m indicating the impulse response of the linear phase filter as shown in FIG. 2A, and the impulse response data h1m indicating the impulse response of the minimum phase filter as shown in FIG. 2D.

When the impulse response data h1m indicating the impulse response of the linear phase filter is supplied, the high frequency convolution arithmetic section B1 carries out the foregoing convolution arithmetic on the basis of the impulse response data h1m. Thus, the high frequency convolution arithmetic section B1 functions as a high pass linear phase filter, which has a constant delay phase characteristic as shown in FIG. 2B and a gain characteristic as shown in FIG. 2C, on the digital audio signal X1.

When the impulse response data h1m indicating the impulse response of the minimum phase filter is supplied, on the other hand, the high frequency convolution arithmetic section B1 carries out the foregoing convolution arithmetic on the basis of the impulse response data h1m. Thus, the high frequency convolution arithmetic section B1 functions as a high pass minimum phase filter, which has a phase characteristic as shown in FIG. 2E and a gain characteristic as shown in FIG. 2F, on the digital audio signal X1.

The digital audio signal X1 is input into the low frequency convolution arithmetic section C1. The low frequency convolution arithmetic section C1 carries out convolution arithmetic on the signal X1 and impulse response data h1n composed of an N+1 coefficient sequence, which is supplied from the impulse characteristic control section 21 as described later. Thus, of the whole frequency band of the digital audio signal X1, the frequency of a signal component in a low frequency band BL1, except for the high frequency band BH1 divided in the high frequency convolution arithmetic section B1, is divided. After the gain, phase characteristic, and the like of the divided signal component are adjusted, the divided signal component is output as the output signal X12.

In other words, since the low frequency convolution arithmetic section C1 carries out the foregoing convolution arithmetic on the basis of the impulse response data h1n, the low frequency convolution arithmetic section C1 functions as a low pass digital filter on the digital audio signal X1. Also, filter characteristics such as the low frequency band (pass band) BL1, gain, phase characteristic, and the like are adjusted on the basis of the impulse response data h1n, so that the frequency convolution arithmetic section C1 has a channel divider function for carrying out frequency division on the foregoing low frequency band BL1, and a graphic equalizer function.

Furthermore, the impulse characteristic control section 21 also supplies the low frequency convolution arithmetic section C1 with the impulse response data h1n indicating the impulse response of the linear phase filter, and the impulse response data h1n indicating the impulse response of the minimum phase filter, as in the case of the high frequency convolution arithmetic section B1.

When the impulse response data h1n indicating the impulse response of the linear phase filter is supplied, the low frequency convolution arithmetic section C1 carries out the foregoing convolution arithmetic on the basis of the impulse response data h1n. Thus, the low frequency convolution arithmetic section C1 functions as a low pass linear phase filter on the digital audio signal X1. When the impulse response data h1n indicating the impulse response of the minimum phase filter is supplied, on the other hand, the low frequency convolution arithmetic section C1 carries out the foregoing convolution arithmetic on the basis of the impulse response data h1n. Thus, the low frequency convolution arithmetic section C1 functions as a low pass minimum phase filter on the digital audio signal X1.

As described above, the high frequency convolution arithmetic section B1 functions as the high pass linear phase filter or the high pass minimum phase filter in accordance with the impulse response data h1m. The low frequency convolution arithmetic section C1 functions as the low pass linear phase filter or the low pass minimum phase filter in accordance with the impulse response data h1n. Accordingly, the high frequency convolution arithmetic section B1 and the low frequency convolution arithmetic section C1 function as the graphic equalizer which has a gain-frequency characteristic as shown in FIG. 2G in the whole frequency band of the output signals X11 and X12.

The digital audio signal X1 is composed of a sequence of sampled values (data sequence) according to the sampling theorem of Nyquist. The impulse characteristic control section 21 supplies the high frequency convolution arithmetic section B1 with the impulse response data h1m, which is composed of the M+1 coefficient sequence represented by h1m (m=1, 2, 3, . . . , M+1) according to the sampling theorem. Also, the impulse characteristic control section 21 supplies the low frequency convolution arithmetic section C1 with the impulse response data h1n, which is composed of the N+1 coefficient sequence represented by h1n (n=1, 2, 3, . . . , N+1) according to the sampling theorem.

The sampling number of the impulse response data h1m for carrying out signal processing on the signal component in the high frequency band BH1 is lower than that of the impulse response data h1n for carrying out signal processing on the signal component in the low frequency band BL1. Namely, an equation of N+1>M+1 holds.

Therefore, if the sampling number (M+1) is a few, it is possible to subject the signal component in the high frequency band BH1 to the signal processing. Also, it is possible to reduce the amount of total data necessary for carrying out the convolution arithmetic in the high frequency band BH1 and the low frequency band BL1, and to miniaturize the configuration of the signal processing unit A1.

A delay time τ11, which is designated by delay time data d1 supplied by a delay time control section 22 described later, is set to a delay section D1. The delay section D1 delays the output signal X11 from the high frequency convolution arithmetic section B1 with the time τ11, and outputs the delayed digital audio signal X1(H).

In other words, when a sampling period which is decided on the basis of the foregoing sampling theorem of Nyquist is represented by Ts, the delay time τ11 proportionate to the delay time data d1 and the sampling period Ts (time proportionate to d1×Ts including 0) is set to the delay section D1.

A delay time τ12, which is designated by delay time data e1 supplied by the delay time control section 22 described later, is set to a delay section E1. The delay section E1 delays the output signal X12 from the low frequency convolution arithmetic section C1 with the time τ12, and outputs the delayed digital audio signal X1(L).

In other words, when a sampling period which is decided on the basis of the foregoing sampling theorem of Nyquist is represented by Ts, the delay time τ12 proportionate to the delay time data e1 and the sampling period Ts (time proportionate to e1×Ts including 0) is set to the delay section E1.

As described above, the delay times τ11 and τ12 are set to the delay sections D1 and E1 in accordance with the delay time data d1 and e1, respectively. Therefore, the delay sections D1 and E1 have a time alignment function for adjusting the propagation delay time of each output signal X11 and X12.

Each of the other signal processing sections A2, A3 to Ap basically has the same configuration as the signal processing section A1. Each of the high frequency convolution arithmetic sections B2, B3 to Bp basically has the same configuration as the high frequency convolution arithmetic section B1. Each of the low frequency convolution arithmetic sections C2, C3 to Cp basically has the same configuration as the low frequency convolution arithmetic section C1. Each of the delay sections D2, D3 to Dp basically has the same configuration as the delay section D1. Each of the delay sections E2, E3 to Ep basically has the same configuration as the delay section E1.

Each high frequency convolution arithmetic section B2, B3 to Bp carries out convolution arithmetic on each digital audio signal X2, X3 to Xp and each of impulse response data sets h2m, h3m to hpm. Each of the impulse response data sets h2m, h3m to hpm is composed of an M+1 coefficient sequence supplied from the impulse characteristic control section 21. Thus, each high frequency convolution arithmetic section B2, B3 to Bp has the channel divider function and the graphic equalizer function. By the channel divider function and the graphic equalizer function, frequency division and the adjustment of gain and a phase characteristic are carried out on a signal component of each digital audio signal X2, X3 to Xp in each high frequency band BH2, BH3 to BHp. Furthermore, when impulse response data h2m, h3m to hpm indicating the impulse response of a linear phase filter is supplied, each high frequency convolution arithmetic section B2, B3 to Bp functions as a high pass linear phase filter. When impulse response data h2m, h3m to hpm indicating the impulse response of a minimum phase filter is supplied, each high frequency convolution arithmetic section B2, B3 to Bp functions as a high pass minimum phase filter.

Each low frequency convolution arithmetic section C2, C3 to Cp carries out convolution arithmetic on each digital audio signal X2, X3 to Xp and each of impulse response data sets h2n, h3n to hpn. Each of the impulse response data sets h2n, h3n to hpn is composed of an N+1 coefficient sequence supplied from the impulse characteristic control section 21. Thus, each high frequency convolution arithmetic section C2, C3 to Cp has the channel divider function and the graphic equalizer function. By the channel divider function and the graphic equalizer function, frequency division and the adjustment of gain and a phase characteristic are carried out on a signal component of each digital audio signal X2, X3 to Xp in each low frequency band BL2, BL3 to BLp. Furthermore, when impulse response data h2n, h3n to hpn indicating the impulse response of a linear phase filter is supplied, each high frequency convolution arithmetic section C2, C3 to Cp functions as a high pass linear phase filter. When impulse response data h2n, h3n to hpn indicating the impulse response of a minimum phase filter is supplied, each high frequency convolution arithmetic section C2, C3 to Cp functions as a high pass minimum phase filter.

Delay times τ21, τ31 to τp1, which are designated by delay time data d2, d3 to dp supplied from the delay time control section 22, are set to the delay sections D2, D3 to Dp, respectively. Each delay section D2, D3 to Dp delays output signal X21, X31 to Xp1 output from each high frequency convolution arithmetic section B2, B3 to Bp, and outputs a delayed digital audio signal X2(H), X3(H) to Xp(H).

In other words, as in the case of the delay section D1, each delay section D2, D3 to Dp also has the time alignment function by setting the delay time τ21, τ31 to τp1 (including the case of τ21=0, τ31=0, and τp1=0). Here, the delay time τ21, τ31 to τp1 proportionate to the sampling period Ts is in accordance with the delay time data d2, d3 to dp.

Delay times τ22, τ32 to τp2, which are designated by delay time data d22, d32 to dp2 supplied from the delay time control section 22, are set to the delay sections E2, E3 to Ep, respectively. Each delay section E2, E3 to Ep delays output signal X22, X32 to Xp2 output from each low frequency convolution arithmetic section C2, C3 to Cp, and outputs a delayed digital audio signal X2(L), X3(L) to Xp(L).

In other words, as in the case of the delay section E1, each delay section E2, E3 to Ep also has the time alignment function by setting the delay time τ22, τ32 to τp2 (including the case of τ22=0, τ32=0, and τp2=0). Here, the delay time τ22, τ32 to τp2 proportionate to the sampling period Ts is in accordance with the delay time data d22, d32 to dp2.

Each digital audio signal X2, X3 to Xp is composed of a sequence of sampled values (data sequence) according to the sampling theorem of Nyquist. Thus, the impulse characteristic control section 21 supplies each high frequency convolution arithmetic section B2, B3 to Bp with each of the impulse response data sets h2m, h3m to hpm. Each of the impulse response data sets h2m, h3m to hpm is composed of an M+1 coefficient sequence, which is represented by h2m(m=1, 2, 3, . . . M+1), h3m (m=1, 2, 3, . . . M+1) to hpm (m=1, 2, 3, . . . M+1) according to the sampling theorem.

The impulse characteristic control section 21 also supplies each low frequency convolution arithmetic section C2, C3 to Cp with each of the impulse response data sets h2n, h3n to hpn. Each of the impulse response data sets h2n, h3n to hpn is composed of an N+1 coefficient sequence, which is represented by h2n (n=1, 2, 3, . . . N+1), h3n (n=1, 2, 3, . . . N+1) to hpn (n=1, 2, 3, . . . N+1) according to the foregoing sampling theorem.

The sampling number of each of the impulse response data sets h2m, h3m to hpm for carrying out signal processing on the signal component in the high frequency band BH2, BH3 to BHp is set lower than that of each of the impulse response data sets h2n, h3n to hpn for carrying out signal processing on the signal component in the low frequency band BL2, BL3 to BLp. Namely, an equation of N+1>M+1 holds. Therefore, even if the sampling number (M+1) of each high frequency convolution arithmetic section B2, B3 to Bp is a few, it is possible to subject the signal component in the high frequency band BH2, BH3 to BHp to the signal processing. Also, it is possible to reduce the amount of total data necessary for carrying out the convolution arithmetic in the high frequency band BH2, BH3 to BHp and the low frequency band BL2, BL3 to BLp, and to miniaturize the configuration of the signal processing unit A2, A3 to Ap.

The impulse characteristic control section 21 and the delay time control section 22 are composed of a microprocessor (MPU), DSP (digital signal processor), or a digital circuit which is provided in a control unit 20 for intensively managing the operation of the acoustic characteristic adjustment device 10.

The control unit 20 is connected to an operation section 30 from which a listener (or audience) inputs desired operation to the acoustic characteristic adjustment device 10. The control unit 20 has operation means such as an operation switch and an operation key, and display means such as a liquid crystal display. By the operation switch and the operation key as input means, each filter characteristic of the high frequency convolution arithmetic section B1 to Bp, each filter characteristic of the low frequency convolution arithmetic section C1 to Cp, and each delay time of the delay section D1 to Dp and E1 to Ep are independently adjusted. On the liquid crystal display, operation information such as an operating procedure is displayed in accordance with control from the control unit 20. The liquid crystal display also makes it possible for the listener or the like to carry out interactive operation, such as displaying information input by the listener or the like with the operation means for announcement.

Being apparent from the following description of operation, when the listener or the like operates the operation means while looking at the display means, the control unit 20, the impulse characteristic control section 21, and the delay time control section 22 adjust the frequency division characteristic, gain, phase characteristic, and delay time of each signal processing unit A1 to Ap, which has the foregoing channel divider function, graphic equalizer function, and timing alignment function. Therefore, it is possible to adjust the acoustic characteristics of sound in a listening position or the like to desired characteristics.

Next, the operation of the acoustic characteristic adjustment device 10 having such configuration will be described.

When the listener or the like operates the predetermined operation means provided in the operation section 30 to designate a desired channel, the control unit 20 controls the signal processing unit of the designated channel.

Taking a case where the signal processing unit A1 is designated as an example, the control unit 20 makes the foregoing display means display the operating procedure and that the signal processing unit A1 of a first channel is designated, in order to encourage the listener or the like to input desired acoustic characteristics (hereinafter called “target characteristics”). To be more specific, the control unit 20 encourages the listener or the like to input the characteristics of the high frequency convolution arithmetic section. B1 and the low frequency convolution arithmetic section C1, and the distances from each speaker of the first channel to the listening position or the like.

In response to this display, the listener or the like designates one of the linear phase filter and the minimum phase filter as the type of filter to be realized by the high frequency convolution arithmetic section B1, and designates one of the linear phase filter and the minimum phase filter as the type of filter to be realized by the low convolution arithmetic section C1. Then, the control unit 20 supplies data which represents the designated type of filter to the impulse characteristic control section 21.

In other words, the listener or the like can separately designate each of the high frequency convolution arithmetic section B1 and the low frequency convolution arithmetic section C1 to one of the linear phase filter and the minimum phase filter. The listener can or the like also switch the designation between the minimum phase filter and the linear phase filter.

The listener or the like inputs a desired high frequency band (pass band) BH1 with which the high frequency convolution arithmetic section B1 carries out frequency division, and cutoff characteristics in its attenuation band (high pass and low pass cutoff frequencies and a cutoff slope being the attenuation of each cutoff frequency). Thus, the control unit 20 supplies the impulse characteristic control section 21 with data indicating the input high frequency band BH1 and the cutoff characteristics.

When the listener or the like inputs desired gain (the amount of boost or the amount of cut) on a narrow band of ⅓ oct basis in the high frequency band (pass band) BH1, the control unit 20 supplies the impulse characteristic control section 21 with data indicating the input gain of ⅓ oct.

When the listener or the like inputs a desired low frequency band (pass band) BL1 with which the low frequency convolution arithmetic section C1 carries out frequency division, and cutoff characteristics in its attenuation band (high pass and low pass cutoff frequencies and a cutoff slope being the attenuation of each cutoff frequency). Thus, the control unit 20 supplies the impulse characteristic control section 21 with data indicating the input low frequency band BL1 and the cutoff characteristics. When the listener or the like inputs desired gain (the amount of boost or the amount of cut) on a narrow band of ⅓ oct basis in the foregoing low frequency band (pass band) BL1, the control unit 20 supplies the impulse characteristic control section 21 with data indicating the input gain of ⅓ oct.

By operating the operation section 30 according to this embodiment, it is possible to variably designate the cutoff characteristic related to each of the high frequency band BH1 and the low frequency band BL1 in a range of through (0 dB) to −72 dB/oct at the maximum every −6 dB/oct, separately.

The listener or the like designates the target characteristic of each of the high frequency convolution arithmetic section B1 and the low frequency convolution arithmetic section C1 in such a manner. Then, the impulse characteristic control section 21 generates the impulse response data h1m, which represents the impulse response of the high pass filter satisfying the designated target characteristic, on the basis of the foregoing data related to the high frequency convolution arithmetic section B1 supplied from the control unit 20. The data related to the high frequency convolution arithmetic section B1 includes the type of filter, the high frequency band BH1, the amount of boost or the amount of cut on the narrow band of ⅓ oct basis, and the cutoff characteristic thereof. The impulse characteristic control section 21 generates the impulse response data h1m, which is composed of the M+1 samples of coefficient sequence h1m (m=1, 2, 3, . . . M+1), and supplies it to the high frequency convolution arithmetic section B1.

In other words, when the linear phase filter is designated as the type of filter related to the high frequency convolution arithmetic section B1, the impulse characteristic control section 21 generates the impulse response data h1m, which has the gain and phase characteristic of the linear phase filter and satisfies the target characteristic. Then, the impulse characteristic control section 21 supplies the impulse response data h1m to the high frequency convolution arithmetic section B1. When the minimum phase filter is designated, the impulse characteristic control section 21 generates the impulse response data h1m, which has the frequency characteristic and phase characteristic of the minimum phase filter and satisfies the target characteristic, and supplies it to the high frequency convolution arithmetic section B1.

Furthermore, the impulse characteristic control section 21 generates the impulse response data h1n, which represents the impulse response of the low pass filter satisfying the designated target characteristic, on the basis of the foregoing data related to the low frequency convolution arithmetic section C1 supplied from the control unit 20. The data related to the low frequency convolution arithmetic section C1 includes the type of filter, the low frequency band BL1, the amount of boost or the amount of cut in every narrow band of ⅓oct, and the cutoff characteristic thereof. The impulse characteristic control section 21 generates the impulse response data h1n composed of the N+1 samples of a coefficient sequence h1n (n=1, 2, 3, . . . N+1), and supplies it to the low frequency convolution arithmetic section C1.

In other words, when the linear phase filter is designated as the type of filter related to the low frequency convolution arithmetic section C1, the impulse characteristic control section 21 generates the impulse response data h1n, which has the frequency characteristic and phase characteristic of the linear phase filter and satisfies the target characteristic. Then, the impulse characteristic control section 21 supplies the impulse response data h1n to the low frequency convolution arithmetic section C1. When the minimum phase filter is designated, the impulse characteristic control section 21 generates the impulse response data h1n, which has the gain and phase characteristic of the minimum phase filter and satisfies the target characteristic, and supplies it to the low frequency convolution arithmetic section C1.

The high frequency convolution arithmetic section B1 exerts the channel divider function and the graphic equalizer function, by carrying out the convolution arithmetic on the digital audio signal X1 on the basis of the impulse response data h1m. The low frequency convolution arithmetic section C1 exerts the channel divider function and the graphic equalizer function, by carrying out the convolution arithmetic on the digital audio signal X1 on the basis of the impulse response data h1n.

The listener or the like inputs the distance L11 from the speaker connected to a route on the side of the delay section D1 to the listening position or the like, and the distance L12 from the speaker connected to a route on the side of the delay section E1 to the listening position or the like, in accordance with the operating procedure displayed on the foregoing display means. Then, the control unit 20 supplies the delay time control section 22 with data representing each of the distances L11 and L12.

The delay time control section 22 calculates alignment times T11 and T12 by dividing each of the distances L11 and L12 by the velocity of sound. The alignment time T11 is time which sound emitted from the speaker connected to the route on the side of the delay section D1 takes to reach the listening position or the like. The alignment time T12 is time which sound emitted from the speaker connected to the route on the side of the delay section E1 takes to reach the listening position or the like.

Furthermore, as described in the following <1> to <4>, the delay time control section 22 generates delay time data d1 and e1 for setting the delay times τ11 and τ12 of the delay sections D1 and E1, in accordance with the designated type of filter related to the high frequency convolution arithmetic section B1 and the low frequency convolution arithmetic section C1. Then, the delay time control section 22 supplies the delay time data d1 and e1 to the delay sections D1 and E1, respectively.

<1> In the case where both of the high frequency convolution arithmetic section B1 and the low frequency convolution arithmetic section C1 are linear phase filters:

In such a case, the delay time control section 22 calculates correction time ΔT11 by multiplying a half [(N−M)/2] of a value (N−M), which is got when the lower sampling number (M+1) is subtracted from the foregoing larger sampling number (N+1), by a sampling period Ts. Furthermore, the delay time control section 22 calculates a delay time τ11, which is the sum (T11+ΔT11) of the correction time ΔT11 and the alignment time T11 calculated from the foregoing distance L11. Then, the delay time control section 22 supplies delay time data d1 representing the delay time τ11 to the delay section D1, so that the delay time τ11 of the delay section D1 is set at the foregoing time (T11+ΔT11).

As to a delay time τ12 of the delay section E1, on the other hand, the delay time control section 22 sets the alignment time T12 calculated from the foregoing distance L12 as the delay time τ12. Since the delay time control section 22 supplies delay time data e1 to the delay section E1, the delay time τ12 of the delay section E1 is set at the alignment time T12.

As described above, the delay time control section 22 exerts the time alignment function by adjusting the delay times τ11 and τ12 of the delay sections D1 and E1 in accordance with each of the distances L11 and L12 from each of the foregoing designated speakers to the listening position or the like.

Furthermore, a case where both of the high frequency convolution arithmetic section B1 and the low frequency convolution arithmetic section C1 function as the linear phase filters will be considered. In such a case, the output signal X12 of the high frequency convolution arithmetic section lags by a value of [(N−M)/2] with respect to the output signal X11 of the high frequency convolution arithmetic section B1, according to the characteristic of the linear phase filter, that is, the constant delay time, as described with reference to FIG. 2A. In other words, when both of the high frequency convolution arithmetic section B1 and the low frequency convolution arithmetic section C1 function as the linear phase filters, the high frequency convolution arithmetic section B1 and the low frequency convolution arithmetic section C1 carry out the convolution arithmetic on a digital audio signal X1 and impulse response data h1m and h1n, respectively. The digital audio signal X1 is composed of a sequence of sampled values x0, x1 . . . as shown in FIG. 3A. Each of impulse response data sets h1m and h1n has the characteristic of the linear phase filter as shown in FIG. 3B. Thus, the high frequency convolution arithmetic section B1 and the low frequency convolution arithmetic section C1 output the output signals X11 and X12 having a lag (phase delay) as shown in FIG. 3D, respectively. The delay time control section 22 calculates difference in time of the lag between the output signals X11 and X12 as the correction time ΔT11. The delay time control section 22 sets the sum (T11+ΔT11) of the alignment time T11 calculated from the distance L11 and the correction time ΔT11, as the delay time τ11 of the delay section D1. Accordingly, difference in the phase between the output signals X11 and X12 is compensated in passing through the delay sections D1 and E1. Therefore, the total delay time and total phase of sound emitted from each speaker are aligned in the listening position or the like, and hence it is possible to reproduce sound with high quality.

<2> In the case where both of the high frequency convolution arithmetic section B1 and the low frequency convolution arithmetic section C1 are minimum phase filters:

In such a case, the delay time control section 22 supplies delay time data d1 representing the alignment time T11 calculated from the foregoing distance L11 to the delay section D1, so that the alignment time T11 is set as a delay time τ11. The delay time control section 22 also supplies delay time data e1 representing the alignment time T12 calculated from the foregoing distance L12 to the delay section E1. Thus, the alignment time T12 is set as a delay time τ12.

When both of the high frequency convolution arithmetic section B1 and the low frequency convolution arithmetic section C1 are the minimum phase filters, the convolution arithmetic on a digital audio signal X1 and each of impulse response data sets h1m and h1n can generate output signals X11 and X12 without time delay. In other words, when both of the high frequency convolution arithmetic section B1 and the low frequency convolution arithmetic section C1 function as the minimum phase filters, the high frequency convolution arithmetic section B1 and the low frequency convolution arithmetic section C1 carry out the convolution arithmetic on the digital audio signal X1 and each of the impulse response data sets h1m and h1n. The digital audio signal X1 is composed of the sequence of sampled values x0, x1 . . . as shown in FIG. 3A. Each of the impulse response data sets h1m and h1n has the characteristic of the minimum phase filter as shown in FIG. 3C. Thus, the high frequency convolution arithmetic section B1 and the low frequency convolution arithmetic section C1 output the output signals X11 and X12 without a lag (phase delay) as shown in FIG. 3E, respectively. The delay time control section 22 adjusts the delay times τ11 and τ12 of the delay sections D1 and E1 in accordance with the distances L11 and L12 from each of the foregoing designated speakers to the listening position or the like. Therefore, it is possible to exert the time alignment function for aligning the total delay time and the total phase of sound emitted from each speaker in the listening position or the like, and it is also possible to reproduce sound with high quality.

<3> In the case where the high frequency convolution arithmetic section B1 is a linear phase filter, and the low frequency convolution arithmetic section C1 is a minimum phase filter:

In such a case, the delay time control section 22 sets the alignment time T11 calculated from the foregoing designated distance L11 as a delay time τ11, and supplies delay time data d1 to the delay section D1. Thus, the delay time τ11 of the delay section D1 is set at the alignment time T11.

As to a delay time τ12 of the delay section E1, on the other hand, the delay time control section 22 calculates correction time ΔT12 by multiplying a half value [(M+1) /2] of the foregoing sampling number (M+1) by a sampling period Ts. Furthermore, the correction time ΔT12 is added to the alignment time T12 calculated from the distance L12, to calculate the delay time τ12. Then, delay time data e1 representing the delay time τ12 is supplied to the delay section E1, so that the delay time τ12 of the delay section E1 is set at the foregoing time (T12+ΔT12).

The delay time control section 22, as described above, exerts the time alignment function, by adjusting the delay times τ11 and τ12 of the delay sections D1 and E1 in accordance with the distances L11 and L12 from each of the foregoing designated speakers to the listening position or the like.

Furthermore, when the high frequency convolution arithmetic section B1 is the linear phase filter and the low frequency convolution arithmetic section C1 is the minimum phase filter, if convolution arithmetic is carried out on a digital audio signal X1 and each of impulse response data sets h1m and h1n, output signals X11 and X12 as shown in FIGS. 3D and 3E are generated in accordance with the characteristics of the linear phase filter and the minimum phase filter as shown in FIGS. 3B and 3C. Also, the output signal X11 of the high frequency convolution arithmetic section B1 lags (delays in phase) by a value of [(M+1) /2] with respect to the output signal X12 of the low frequency convolution arithmetic section C1. The delay time control section 22 calculates time of a lag as the correction time ΔT12, and sets time (T12+ΔT12), which is the sum of the alignment time τ12 calculated from the distance L12 and the correction time ΔT12, as the delay time τ12 of the delay section E1. Therefore, difference in the phase between the output signals X11 and X12 is compensated in passing through the delay sections D1 and E1. Accordingly, it is possible to align the total delay time and total phase of sound emitted from each speaker in the listening position or the like, and hence it is possible to reproduce sound with high quality.

<4> In the case where the high frequency convolution arithmetic section B1 is a minimum phase filter, and the low frequency convolution arithmetic section C1 is a linear phase filter:

In such a case, the delay time control section 22 calculates correction time ΔT11 by multiplying a half value [(N+1) /2] of the foregoing sampling number (N+1) by a sampling period Ts. Furthermore, the delay time control section 22 calculates the sum (T11+ΔT11) of the correction time ΔT11 and the alignment time T11 calculated from the distance L11, as a delay time τ11. Then, the delay time control section 22 supplies the delay section D1 with delay time data d1 representing the delay time τ11, so that the delay time τ11 of the delay section D1 is set at the foregoing time (T11+ΔT11).

As to a delay time τ12 of the delay section E1, on the other hand, the delay time control section 22 sets the alignment time T12 calculated from the distance L12 as the delay time τ12. The delay time control section 22 supplies delay time data e1 to the delay section E1, so that the delay time τ12 of the delay section E1 is set as the alignment time T12.

The delay time control section 22, as described above, exerts the time alignment function, by adjusting the delay times τ11 and τ12 of the delay sections D1 and E1 in accordance with the distances L11 and L12 from each of the foregoing designated speakers to the listening position or the like.

Furthermore, when the high frequency convolution arithmetic section B1 is the minimum phase filter and the low frequency convolution arithmetic section C1 is the linear phase filter, if the convolution arithmetic is carried out on a digital audio signal X1 and each of impulse response data sets h1m and h1n, output signals X11 and X12 as shown in FIGS. 3D and 3E are generated in accordance with the characteristics of the linear phase filter and the minimum phase filter as shown in FIGS. 3B and 3C. Also, the output signal X12 of the low frequency convolution arithmetic section C1 lags by a value of [(N+1) /2] with respect to the output signal X11 of the high frequency convolution arithmetic section B1. The delay time control section 22 calculates time of a lag as the correction time ΔT11, and time (T11+ΔT11), which is the sum of the alignment time T11 calculated from the distance L11 and the correction time ΔT11, is set as the delay time τ11 of the delay section D1. Thus, difference in the phase between the output signals X11 and X12 is compensated in passing through the delay sections D1 and E1. Therefore, it is possible to align the total delay time and total phase of sound emitted from each speaker in the listening position or the like, and hence it is possible to reproduce sound with high quality.

When the other signal processing units A2, A3 to Ap are designated, as in the case of the signal processing unit A1, the impulse characteristic control section 21, the delay time control section 22, and the like set each of the characteristics of the high frequency convolution arithmetic sections B2, B3 to Bp, the low frequency convolution arithmetic sections C2, C3 to Cp, the delay sections D2, D3 to Dp, and E2, E3 to Ep at a target characteristic desired by the listener or the like.

According to the acoustic characteristic adjustment device 10 of this embodiment, as described above, the listener or the like (namely, a listener or an audience) operates the operation section 30 and can separately and variably set the high frequency convolution arithmetic sections B1 to Bp and the low frequency convolution arithmetic sections C1 to Cp in the signal processing units A1 to Ap at one of the linear phase filter and the minimum phase filter. Also, the delay time of each of the delay sections D1 to Dp and E1 to Ep is automatically set so as to align the total delay time and total phase of sound emitted from each speaker in the listening position or the like (namely, listening position or watching position), in accordance with the type of filter. Therefore, it is possible to provide the various channel divider functions, graphic equalizer functions, and time alignment functions for the listener or the like, in accordance with an intended purpose and the like.

When the acoustic characteristic adjustment device 10 is applied to AV equipment for reproducing images and sound, the listener or the like sets both of the high frequency convolution arithmetic sections B1 to Bp and the low frequency convolution arithmetic sections C1 to Cp in the signal processing units A1 to Ap as the minimum phase filters. Thus, it is possible to eliminate time delay during the convolution arithmetic in the high frequency convolution arithmetic sections B1 to Bp and the low frequency convolution arithmetic sections C1 to Cp. Therefore, it is possible to generate sound matching with images displayed on the display or the like in the listening position (or watching position). In other words, it is possible to generate sound with acoustic characteristics matching with the images in the listening position (or watching position).

The sampling number (M+1) of each of the impulse response data sets h1m to hpm is lower than the sampling number (N+1) of each of the impulse response data sets h1n to hpn. Each of the high frequency convolution arithmetic sections B1 to Bp and each of the low frequency convolution arithmetic sections C1 to Cp carry out the convolution arithmetic on the basis of the respective impulse response data sets h1m to hpm and h1n to hpn. Therefore, it is possible to reduce the total amount of the impulse response data h1m to hpm and h1n to hpn, which is necessary for carrying out the convolution arithmetic, and to realize the miniaturization of the signal processing units A1 to Ap.

In the foregoing description, the target characteristic of each channel and the type of filter are separately input. The present invention, however, is not limited thereto, and operation may be input in another way.

For example, a database having the so-called searched data group, in which the target characteristic of each channel and the type of filter are related to each other by predetermined relations, may be provided in advance. When the listener or the like properly inputs one or both of the target characteristic and the type of filter, the target characteristic of each channel and the type of filter related to the input one may be automatically searched, to automatically set the target characteristic of each channel and the type of filter. To be more specific, taking a case where a system has a plurality of channels, for example, the listener or the like may input one or both of the target characteristic and the type of filter with respect to some channels without especially designating the channels. Only by doing so, the target characteristic and the type of filter of each of the plurality of channels related to the input target characteristic and the type of filter may be automatically searched and automatically set. In such configuration, the listener or the like can integrally input the target characteristic and the type of filter to be set with respect to each of the plurality of channels with easy operation, and hence it is possible to improve convenience.

Otherwise, the foregoing searched data group may be stored in the foregoing database in relation to predetermined sequence. In response to the easy input operation of the listener or the like, an incremental search may be carried out through the foregoing database to set the target characteristic and the type of filter of each channel. In other words, the listener or the like continuously turns on a predetermined operation key, the target characteristic and the type of filter of each channel related to the foregoing sequence are successively searched per predetermined unit of time, and search results are displayed to the listener or the like. When the listener or the like carries out command operation for decision, the target characteristic and the type of filter of each channel displayed at the time of being commanded may be automatically set. Namely, the system may carry out the so-called incremental search. According to such configuration, it is possible to provide superior convenience and operability for the listener or the like.

The target characteristic and the type of filter of each channel may be set at the same time, or may be separately set. In other words, when the target characteristic and the type of filter of each channel have been already set, if the listener inputs only the type of filter, only the input type of filter maybe changed (updated), and the target characteristic which has already been set may be maintained without being changed. When the listener inputs only the target characteristic, on the other hand, only the input target characteristic may be changed (updated), and the type of filter which has already been set may be maintained without being changed. According to such configuration, it becomes possible for the listener to precisely set the target characteristic and the type of filter, and hence improvement in convenience and the like are realized.

### PRACTICAL EXAMPLE

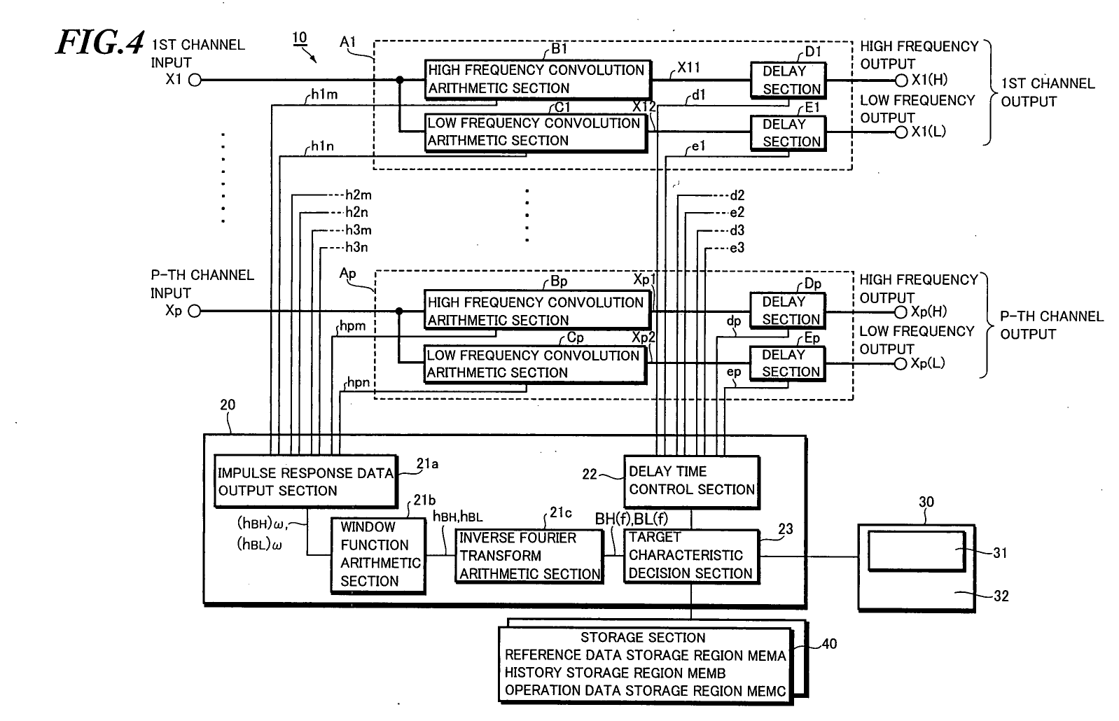

Next, a concrete practical example related to this embodiment will be described with reference to FIGS. 4 to 7.

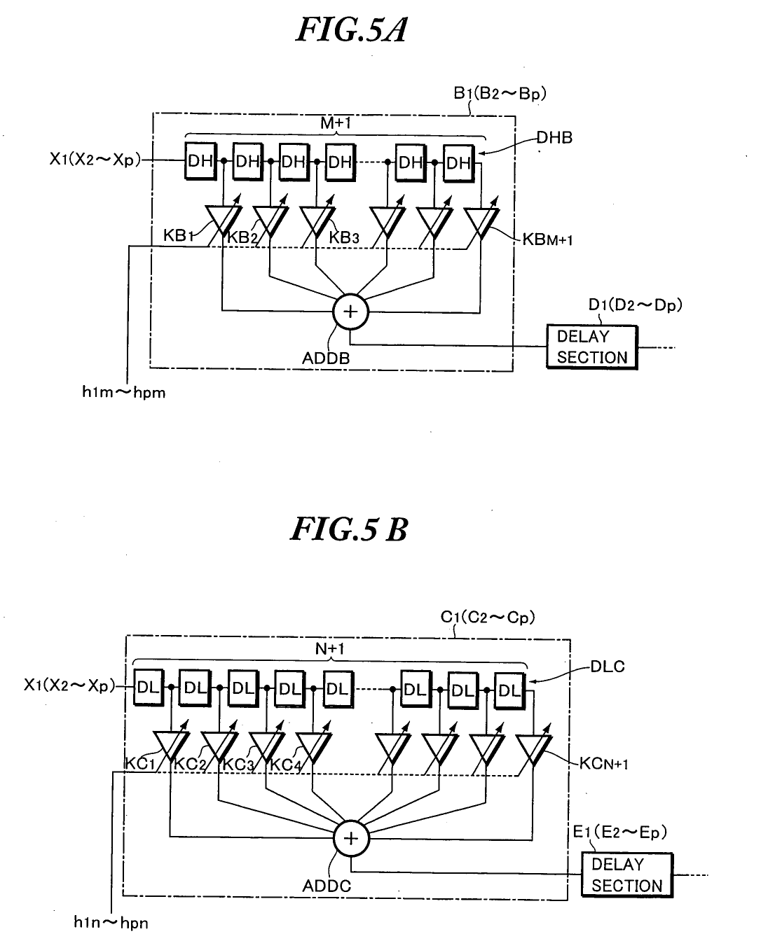

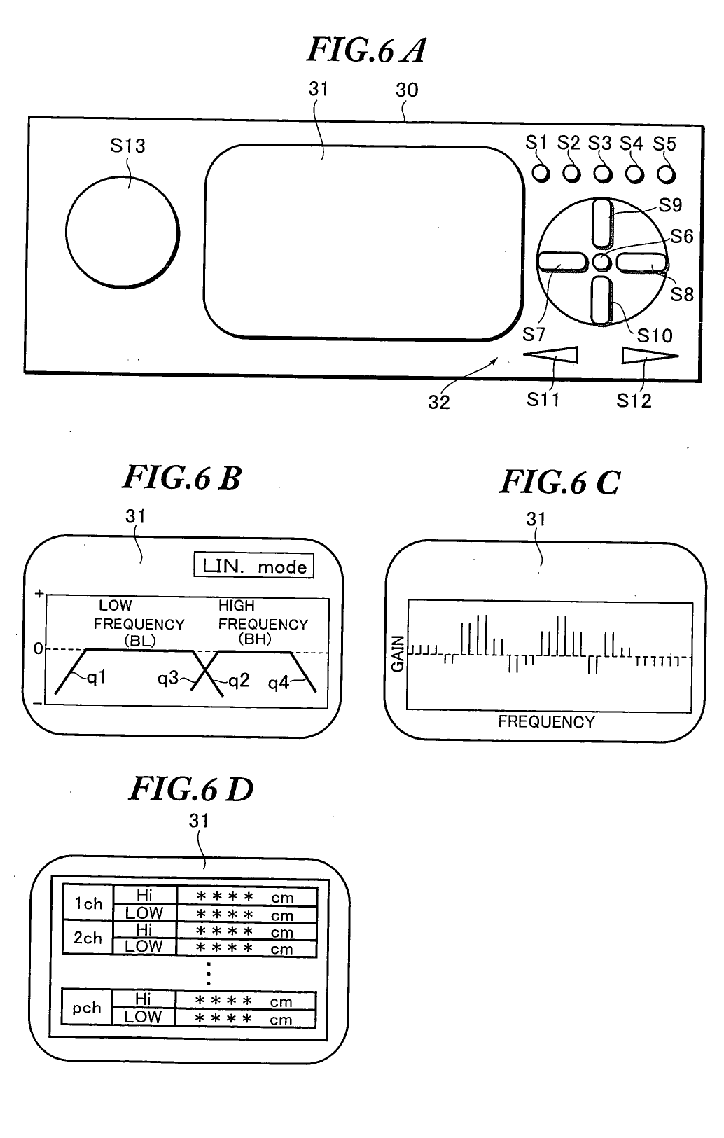

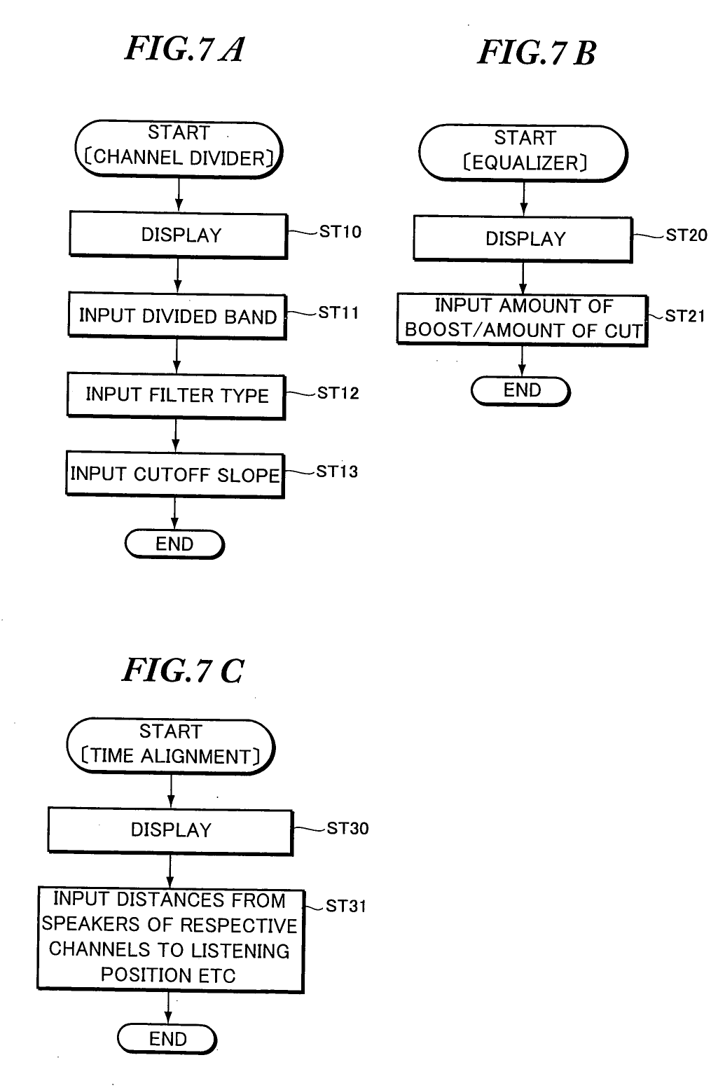

FIG. 4 is a block diagram showing the configuration of an acoustic characteristic adjustment device according to this example. FIGS. 5A and 5B are block diagrams showing the configuration of a high frequency convolution arithmetic section and a low frequency convolution arithmetic section provided in the acoustic characteristic adjustment device. FIGS. 6A to 6D are plan views showing the configuration of an operation section provided in the acoustic characteristic adjustment device. FIGS. 7A to 7C are flowcharts for describing operation. In FIGS. 4 to 6D, the same reference numerals as those of FIG. 1 refer to identical or corresponding parts.

Referring to FIG. 4, an acoustic characteristic adjustment device 10 according to this practical example comprises p-channels of digital signal processing units A1 to Ap, as in the case of FIG. 1. Each of the digital signal processing units A1 to Ap comprises a high frequency convolution arithmetic section B1 to Bp, a low frequency convolution arithmetic section C1 to Cp, and delay sections D1 to Dp and E1 to Ep.

The high frequency convolution arithmetic section B1, as shown in FIG. 5A, comprises a delay circuit DHB composed of dependently connected M+1 delay elements DH, M+1 multipliers KB₁, KB₂ to KB_{M+1} connected to an output end of each delay element DH, and an adder circuit ADDB. The adder circuit ADDB adds up M+1 outputs from the multipliers KB₁, KB₂ to KB_{M+1}, to generate an output signal X11.

A digital audio signal X1 being a sequence of sampled values is successively input to each of the dependently connected delay elements DH in the delay circuit DHB in synchronization with a sampling period Ts. By first-in first-out (FIFO) processing, the delay elements DH hold and update M+1 samples of the digital audio signal X1.

A coefficient value of each of the M+1 multipliers KB₁, KB₂ to KB_{M+1} is set in accordance with impulse response data h1m, which is supplied from a impulse response data output section 21a described later.

In other words, each of coefficient values h11, h12, . . . h1M+1 represented by a coefficient sequence h1m (m=1, 2, 3, . . . M+1) is set with corresponding to each multiplier KB₁, KB₂ to KB_{M+1}, so that the coefficient value h11 set to the multiplier KB₁ is multiplied by the output of the delay element DH at the head of the delay circuit DHB. Furthermore, the coefficient value h12 set to the multiplier KB₂ is multiplied by the output of the delay element DH at the second of the delay circuit DHB. In a like manner, the coefficient value h1M+1 set to the multiplier KB_{M+1} is multiplied by the output of the delay element DH at the last of the delay circuit DHB.

Then, the adder circuit ADDB adds up the M+1 outputs of the multipliers KB₁, KB₂ to KB_{M+1} every sampling period Ts, so that the output signal X11 representing the result of convolution arithmetic is output.

As described above, the high frequency convolution arithmetic section B1, which comprises the M+1 delay elements DH, the M+1 multipliers KB₁, KB₂ to KB_{M+1}, and the adder circuit ADDB, is an FIR digital filter with the M+1 number of taps. The high frequency convolution arithmetic section B1 outputs the output signal X11, by adjusting the gain and phase characteristic of the input digital audio signal X1.

Although it is abbreviated in FIG. 4, each of the other high frequency convolution arithmetic sections B2 to Bp basically has the same configuration as the high frequency convolution arithmetic section B1 shown in FIG. 5A, and is an FIR digital filter with the M+1 number of taps. The high frequency convolution arithmetic sections B2 to Bp generate output signals X21 to Xp1, by carrying out convolution arithmetic with impulse response data h2m to hpm supplied from the impulse response data output section 21a and digital audio signals X2 to Xp, respectively.

The low frequency convolution arithmetic section C1, as shown in FIG. 5B, comprises a delay circuit DLC composed of dependently connected N+1 delay elements DL, N+1 multipliers KC₁, KC₂ to KC_{N+1} connected to an output end of each delay element DL, and an adder circuit ADDC. The adder circuit ADDC adds up N+1 outputs from the multipliers KC₁, KC₂ to KC_{N+1}, to generate an output signal X12.

In the low frequency convolution arithmetic section C1, as in the case of the foregoing high frequency convolution arithmetic section A1, each delay element DL in the delay circuit DLC subjects the digital audio signal X1 to the FIFO processing every sampling period Ts. Also, each of the N+1 multipliers KC₁, KC₂ to KC_{N+1} multiplies each of coefficient values h11, h12, . . . h1N+1, which are represented by a coefficient sequence h1n (n=1, 2, 3, . . . N+1) and supplied from the impulse response data output section 21a described later, by the output of each delay element DL. Then, the adder circuit ADDC adds up N+1 outputs from the multipliers KC₁, KC₂ to KC_{N+1}, to output the output signal X12 representing the result of convolution arithmetic. In other words, the low frequency convolution arithmetic section C1 is an FIR digital filter with the N+1 number of taps.

Although it is abbreviated in FIG. 4, each of the other low frequency convolution arithmetic sections C2 to Cp basically has the same configuration as the low frequency convolution arithmetic section C1 shown in FIG. 5B, and is an FIR digital filter with the N+1 number of taps. The low frequency convolution arithmetic sections C2 to Cp generate output signals X22 to Xp2, by carrying out convolution arithmetic with impulse response data h2n to hpn supplied from the impulse response data output section 21a and digital audio signals X2 to Xp, respectively.

The number of the delay elements DH and the multipliers KB₁ to KB_{M+1} in each of the high frequency convolution arithmetic sections B1 to Bp shown in FIG. 5A, namely the number of taps (M+1) is lower than the number of the delay elements DL and the multipliers KC₁ to KC_{N+1} in each of the low frequency convolution arithmetic sections C1 to Cp shown in FIG. 5B, namely the number of taps (N+1). Accordingly, the number (M+1) of coefficient values of the impulse response data h1m to hpm is lower than the number (N+1) of coefficient values of the impulse response data h1n to hpn. Therefore, as described in the foregoing embodiment, it is possible to reduce the total amount of data required for digital calculation processing, and miniaturize the high convolution arithmetic sections B1 to Bp. In the case where processing using a single convolution arithmetic section is carried out, the number of used delay elements DL and multipliers K is reduced, so that the number of taps is reduced with increase in frequency of a frequency band.

Each of the delay sections D1 to Dp and E1 to Ep comprises a variable shift resister and the like. The variable shift resister variably adjusts each of delay times τ11 to τp1 and τ12 to τp2, in accordance with delay time data d1 to dp and e1 to ep supplied from a delay time control section 22 described later.

A control unit 20 for controlling the whole operation of the acoustic characteristic adjustment device 10 is composed of a DSP, an MPU, or a digital circuit. The control unit 20 comprises the impulse response data output section 21a, a window function arithmetic section 21b, an inverse Fourier transform arithmetic section 21c, the delay time control section 22, and a target characteristic decision section 23.

Furthermore, the control unit 20 is connected to an operation section 30 and a storage section 40 of a semiconductor memory. The operation section is provided with a display section 31 formed by a liquid crystal display or the like, and an operation panel section 32 with switches. When the acoustic characteristic adjustment device 10 is applied to car-mounted AV equipment, for example, the operation section 30 is provided in a front panel of the AV equipment so as to face a driver and a passenger.

The storage section 40 is composed of a rewritable non-volatile semiconductor memory and a read-only semiconductor memory. The read-only semiconductor memory has a reference data storage region MEMA. The non-volatile semiconductor memory has a history storage region MEMB and an operation data storage region MEMC.

The reference data Ha(f) of a frequency spectrum having the characteristic of a linear phase filter in an audible frequency band, and the reference data Hb(f) of a frequency spectrum having the characteristic of a minimum phase filter in the audible frequency band are stored in the reference data storage region MEMA in advance. The reference data Ha(f) and Hb(f) is appropriately decided by an experience and the like.

When an operation switch S4 or S5 described later, which is called a memory key, is operated, the history storage region MEMB stores the characteristics of the high convolution arithmetic sections B1 to Bp, the low frequency convolution arithmetic sections C1 to Cp, and the delay sections D1 to Dp and E1 to Ep of the currently set whole channels.

To be more specific, the history storage region MEMB stores characteristic data, which includes the type of filter currently set to each of the high frequency convolution arithmetic sections B1 to Bp and low frequency convolution arithmetic sections C1 to Cp, the data BH(f) of the frequency spectrum currently realized in each of the high frequency convolution arithmetic sections B1 to Bp, the data BL(f) of the frequency spectrum currently realized in each of the low frequency convolution arithmetic sections C1 to Cp, data d11 to dp1 and e12 to dp2 of the delay times τ11 to τp1 and τ12 to τp2 currently set to each of the delay sections D1 to Dp and E1 to Ep, at least. Such characteristic data is stored in response to the operation of the operation switch S4 or S5.

The operation data storage region MEMC is provided for storing data related to the latest target characteristic input from a listener or the like, in adjusting a channel divider, a graphic equalizer, and time alignment described later.

To be more specific, when the channel divider, the graphic equalizer, and the time alignment are adjusted, the target characteristic, which is input by the listener or the like from the operation section 30, is stored in the operation data storage region MEMC. The target characteristic at least includes the type of filter of each of the high frequency convolution arithmetic sections B1 to Bp and the low frequency convolution arithmetic sections C1 to Cp, the data BH(f) of a frequency spectrum having the characteristic of the linear phase filter or the minimum phase filter of each of the high frequency convolution arithmetic sections B1 to Bp, the data BL(f) of a frequency spectrum having the characteristic of the linear phase filter or the minimum phase filter of each of the low frequency convolution arithmetic sections C1 to Cp, the data d11 to dp1 and e12 to ep2 of delay times τ11 to τp1 and τ12 to τp2 of each of the delay sections D1 to Dp and E1 to Ep, and the like. The data BH(f) of the frequency spectrum is generated by the target characteristic decision section 23 in accordance with the target characteristic. The data BL(f) of the frequency spectrum is generated by the target characteristic decision section 23 in accordance with the target characteristic. The data d11 to dp1 and e12 to ep2 of the delay times τ11 to τp1 and τ12 to τp2 is generated by the delay time control section 22.

When the listener or the like inputs a command for adjusting acoustic characteristics from the operation section 30, namely a command for adjusting the channel divider, the graphic equalizer, and the time alignment, the target characteristic decision section 23 makes the display section 31 display an operating procedure and the like corresponding to the command. Furthermore, when the listener or the like inputs the target characteristic of a desired channel according to the operating procedure, the target characteristic decision section 23 generates the data BH(f) and BL(f) of the frequency spectrums which satisfy the target characteristic in the audible frequency band.

To be more specific, when the command for adjusting the acoustic characteristics is input, the target characteristic decision section 23 searches through the operation data storage region MEMC, to check whether or not the data of the target characteristic related to the channel designated by the listener or the like has already been stored. When the data has not been stored, the target characteristic decision section 23 obtains the reference data Ha(f) and Hb(f) from the reference data storage region MEMA. The target characteristic decision section 23 edits the reference data Ha(f) and Hb(f) in accordance with the data of the target characteristic input by the listener or the like from the operation section 30. Therefore, data BH(f) representing a frequency spectrum in a high frequency band BH corresponding to the target characteristic desired by the listener or the like, and data BL(f) representing a frequency spectrum in a low frequency band BL corresponding thereto are generated. The data BH(f) and BL(f) is stored in the operation data storage region MEMC, after being supplied to the inverse Fourier transform arithmetic section 21c.

When the data of the target characteristic related to the channel designated by the listener or the like has already been stored in the operation data storage region MEMC, the target characteristic decision section 23 obtains data BH(f) and data BL(f) from the operation data storage region MEMC. The data BH(f) is the data of a frequency spectrum in a high frequency band BH corresponding to the channel. The data BL(f) is the data of a frequency spectrum in a low frequency band BL corresponding to the channel. The target characteristic decision section 23 edits the obtained data BH(f) and BL(f) in accordance with the data of the target characteristic input by the listener or the like from the operation section 30. Therefore, new data BH(f) representing a frequency spectrum in a high frequency band BH corresponding to the target characteristic desired by the listener or the like, and new data BL(f) representing a frequency spectrum in a low frequency band BL corresponding thereto are generated. The new data BH(f) and BL(f) is stored in the operation data storage region MEMC, after being supplied to the inverse Fourier transform arithmetic section 21c. Therefore, the corresponding old data is updated to the new data BH(f) and BL(f).

As described above, the target characteristic decision section 23 generates new characteristic data by using characteristic data which has already been stored in the operation data storage region MEMC, and stores the new characteristic data in the operation data storage region MEMC for update. Therefore, it is possible to adjust only desired characteristic of acoustic characteristics which have been already adjusted by the listener or the like. Also, as described above, the characteristic may be adjusted by changing (updating) only the type of filter, with the use of characteristic data which has already been stored in the operation data storage region MEMC.

The inverse Fourier transform arithmetic section 21c performs an inverse Fourier transform on the data BH(f) of the frequency spectrum supplied from the target characteristic decision section 23. Accordingly, impulse response data h_{BH} representing the impulse response of the target characteristic designated by the listener or the like is calculated. The inverse Fourier transform arithmetic section 21c also performs an inverse Fourier transform on the data BL(f) of the frequency spectrum, to calculate impulse response data h_{BL} representing the impulse response of the target characteristic designated by the listener or the like.

The window function arithmetic section 21b multiplies the impulse response data h_{BH} and h_{BL} by a predetermined time window (the so-called load function) ω, in order to calculate each of impulse response data sets (h_{BH} )_{ω} and (h_{BL})_{ω}, which is composed of a coefficient sequence the amplitude of which is adjusted by the time window. In the window function arithmetic section 21b according to this embodiment, a cosine tapered window or a Hanning window is used.

The impulse response data output section 21a sets the foregoing impulse response data (h_{BH})_{ω} as the impulse response data h1m to hpm to be supplied to the high convolution arithmetic section B1 to Bp, and supplies the impulse response data (h_{BH})_{ω} to only the high frequency convolution arithmetic section of the channel designated by the listener or the like in adjusting the acoustic characteristics. Taking a case where a first channel is designated, for example, the impulse response data (h_{BH})_{ω} is supplied to the high frequency convolution arithmetic section B1 as the impulse response data h1m, and each of the coefficients of the multipliers KB₁, KB₂ to KB_{M+1} in the high frequency convolution arithmetic section B1 is set.

Also, the impulse response data output section 21a sets the foregoing impulse response data (h_{BL})_{ω} as the impulse response data h1n to hpn to be supplied to the low convolution arithmetic section C1 to Cp, and supplies the impulse response data (h_{BL})_{ω} to only the low frequency convolution arithmetic section of the channel designated by the listener or the like in adjusting the acoustic characteristics. Taking a case where the first channel is designated, for example, the impulse response data (h_{BL})_{ω} is supplied to the low frequency convolution arithmetic section C1 as the impulse response data h1n, and each of the coefficients of the multipliers KC₁, KC₂ to KC_{N+1} in the low frequency convolution arithmetic section C1 is set.

Furthermore, as described in the following [1] to [4], the target characteristic decision section 23, the inverse Fourier transform arithmetic section 21c, and the window function arithmetic section 21b generate impulse response data sets h1m to hpm to be set to the high frequency convolution arithmetic sections B1 to Bp, and impulse response data sets h1n to hpn to be set to the low frequency convolution arithmetic sections C1 to Cp. Each of the impulse response data sets h1m to hpm has M+1 coefficients. Each of the impulse response data sets h1n to hpn has N+1 coefficients.

[1] When a command for ordering that both of the high frequency convolution arithmetic section B1 to Bp and the low frequency convolution arithmetic section C1 to Cp in each channel are linear phase filters is issued:

When the listener or the like issues such a command, the target characteristic decision section 23 divides an audible frequency band into a high frequency band BH and a low frequency band BL in accordance with target characteristics designated by the listener or the like.

Then, as described above, the target characteristic decision section 23 searches through the storage section 40, to obtain reference data Ha(f) of a frequency spectrum having the characteristic of the linear phase filter from the reference data storage region MEMA, or data BH(f) of a frequency spectrum having the characteristic of the linear phase filter related to the high frequency band BH of the designated channel from the operation data storage region MEMC. The gain and phase characteristic of the obtained data (that is, one of Ha(f) and BH(f) having the characteristic of the linear phase filter) are adjusted in accordance with the target characteristic, to generate new data BH(f) representing a frequency spectrum in the high frequency band BH. Then, the target characteristic decision section 23 supplies the new data BH(f) related to the high frequency band BH to the inverse Fourier transform arithmetic section 21c, and stores the new data BH(f) in the operation data storage region MEMC.

Furthermore, the target characteristic decision section 23 obtains reference data Ha(f) of a frequency spectrum having the characteristic of the linear phase filter from the reference data storage region MEMA, or data BL(f) of a frequency spectrum having the characteristic of the linear phase filter related to the low frequency band BL of the designated channel from the operation data storage region MEMC, in accordance with the search results of the storage section 40. The gain and phase characteristic of the obtained data (that is, one of Ha(f) and BL(f) having the characteristic of the linear phase filter) are adjusted in accordance with the target characteristic, to generate new data BL(f) representing a frequency spectrum in the low frequency band BL. Then, the target characteristic decision section 23 supplies the new data BL(f) related to the low frequency band BL to the inverse Fourier transform arithmetic section 21c, and stores the new data BL(f) in the operation data storage region MEMC.

Then, the inverse Fourier transform arithmetic section 21c performs an inverse Fourier transform on the data BH(f) of the frequency spectrum supplied from the target characteristic decision section 23, to calculate impulse response data h_{BH}, which is composed of a sequence of M+1 coefficients. The inverse Fourier transform arithmetic section 21c also performs the inverse Fourier transform on the data BL(f) of the frequency spectrum, to calculate impulse response data h_{BL}, which is composed of a sequence of N+1 coefficients.

Then, the window function arithmetic section 21b generates and outputs impulse response data (h_{BH})_{ω}, which is composed of a sequence of M+1 coefficients, by multiplying the impulse response data h_{BH} composed of the sequence of the M+1 coefficients by a window function ω composed of a sequence of M+1 sample values. Furthermore, the window function arithmetic section 21b generates and outputs the impulse response data (h_{BL})_{ω}, which is composed of a sequence of N+1 coefficients, by multiplying the impulse response data h_{BL} composed of the sequence of the N+1 coefficients by the window function ω composed of a sequence of N+1 sample values.

Then, the impulse response data output section 21a supplies the foregoing impulse response data (h_{BH})_{ω} to the high frequency convolution arithmetic section of the channel designated by the listener or the like, of the high frequency convolution arithmetic sections B1 to Bp. The impulse response data output section 21a also supplies the foregoing impulse response data (h_{BL})_{ω} to the low frequency convolution arithmetic section of the channel designated by the listener or the like, of the low frequency convolution arithmetic sections C1 to Cp.

Therefore, when the first channel is designated as the channel to be adjusted, the impulse response data output section 21a supplies the impulse response data (h_{BH})_{ω}, which is composed of the sequence of the M+1 coefficients, to the multipliers KB₁, KB₂ to KB_{M+1} in the high frequency convolution arithmetic section B1 as impulse response data h1m. The impulse response data output section 21a also supplies the impulse response data (h_{BL})_{ω}, which is composed of the sequence of the N+1 coefficients, to the multipliers KC₁, KC₂ to KC_{N+1} in the low frequency convolution arithmetic section C1 as impulse response data h1n. Then, each coefficient is adjusted.

[2] When a command for ordering that both of the high frequency convolution arithmetic section B1 to Bp and the low frequency convolution arithmetic section C1 to Cp in each channel are minimum phase filters is issued:

When the listener or the like issues such a command, the target characteristic decision section 23 divides an audible frequency band into a high frequency band BH and a low frequency band BL in accordance with target characteristics designated by the listener or the like.

Then, as described above, the target characteristic decision section 23 obtain reference data Hb(f) of a frequency spectrum having the characteristic of the minimum phase filter from the reference data storage region MEMA, or data BH(f) of a frequency spectrum having the characteristic of the minimum phase filter related to the high frequency band BH of the designated channel from the operation data storage region MEMC and data BL(f) of a frequency spectrum having the characteristic of the minimum phase filter related to the low frequency band BL, in accordance with a result of searching through the storage section 40.

The gain and phase characteristic of one of the obtained reference data Hb(f) and data BH(f) of the frequency spectrum having the characteristic of the minimum phase filter related to the high frequency band BH (that is, one of Hb(f) and BH(f) having the characteristic of the minimum phase filter) are adjusted in accordance with the target characteristic, to generate new data BH(f) representing a frequency spectrum in the high frequency band BH. The gain and phase characteristic of one of the obtained reference data Hb(f) and data BL(f) of the frequency spectrum having the characteristic of the minimum phase filter related to the low frequency band BL (that is, one of Hb(f) and BL(f) having the characteristic of the minimum phase filter) are adjusted in accordance with the target characteristic, to generate new data BL(f) representing a frequency spectrum in the low frequency band BL. Then, the target characteristic decision section 23 supplies the new data BH(f) related to the high frequency band BH and the new data BL(f) related to the low frequency band BL to the inverse Fourier transform arithmetic section 21c, and stores them in the operation data storage region MEMC.

Then, the inverse Fourier transform arithmetic section 21c performs an inverse Fourier transform on the data BH(f) of the frequency spectrum supplied from the target characteristic decision section 23, to calculate impulse response data h_{BH}, which is composed of a sequence of M+1 coefficients. The inverse Fourier transform arithmetic section 21c also performs the inverse Fourier transform on the data BL(f) of the frequency spectrum, to calculate impulse response data h_{BL}, which is composed of a sequence of N+1 coefficients.

Then, the window function arithmetic section 21b outputs impulse response data (h_{BH})_{ω}, which is composed of a sequence of M+1 coefficients, by multiplying the impulse response data h_{BH} composed of the sequence of the M+1 coefficients by a window function ω composed of a sequence of M+1 sample values. Furthermore, the window function arithmetic section 21b outputs impulse response data (h_{BL})_{ω}, which is composed of a sequence of N+1 coefficients, by multiplying the impulse response data h_{BL} composed of the sequence of the N+1 coefficients by a window function ω composed of a sequence of N+1 sample values.

Then, the impulse response data output section 21a supplies the foregoing impulse response data (h_{BH})_{ω} to the high frequency convolution arithmetic section of the designated channel, of the high frequency convolution arithmetic sections B1 to Bp. The impulse response data output section 21a also supplies the foregoing impulse response data (h_{BL})_{ω} to the low frequency convolution arithmetic section of the designated channel, of the low frequency convolution arithmetic sections C1 to Cp. Therefore, the coefficients of the multipliers KB₁, KB₂ to KB_{M+1}, and KC₁, KC₂ to KC_{N+1} provided in the processing sections are adjusted.

[3] When a command for ordering that the high frequency convolution arithmetic section is a linear phase filter and the low frequency convolution arithmetic section is a minimum phase filter, in a combination of the high frequency convolution arithmetic section B1 to Bp and the low frequency convolution arithmetic section C1 to Cp in each channel is issued:

When the listener or the like issues such a command, the target characteristic decision section 23 divides an audible frequency band into a high frequency band BH and a low frequency band BL in accordance with target characteristics designated by the listener or the like.

Then, as described above, the target characteristic decision section 23 searches through the storage section 40. Reference data Ha(f) and Hb(f) of frequency spectrums having the characteristic of the linear and minimum phase filters is obtained from the reference data storage region MEMA, in accordance with a result of searching through the storage section 40. Otherwise, data BH(f) of a frequency spectrum having the characteristic of the linear phase filter related to the high frequency band BH of the designated channel, and data BL(f) of a frequency spectrum having the characteristic of the minimum phase filter related to the low frequency band BL are obtained from the operation data storage region MEMC.

The gain and phase characteristic of one of the obtained reference data Ha(f) and data BH(f) of the frequency spectrum having the characteristic of the linear phase filter related to the high frequency band BH (that is, one of Ha(f) and BH(f) having the characteristic of the linear phase filter) a readjusted in accordance with the target characteristic, to generate new data BH(f) representing a frequency spectrum in the high frequency band BH. The gain and phase characteristic of one of the obtained reference data Hb(f) and data BL(f) of the frequency spectrum having the characteristic of the minimum phase filter related to the low frequency band BL (that is, one of Hb(f) and BL(f) having the characteristic of the minimum phase filter) are adjusted in accordance with the target characteristic, to generate new data BL(f) representing a frequency spectrum in the low frequency band BL. Then, the target characteristic decision section 23 supplies the new data BH(f) related to the high frequency band BH and the new data BL(f) related to the low frequency band BL to the inverse Fourier transform arithmetic section 21c, and stores them in the operation data storage region MEMC.

Then, as in the case of the foregoing [1] and [2], the inverse Fourier transform arithmetic section 21c performs an inverse Fourier transform on each of the data sets BH(f) and BL(f) of the frequency spectrums supplied from the target characteristic decision section 23, and the window function arithmetic section 21b multiplies results by window functions ω. Thus, impulse response data (h_{BH})_{ω} composed of a sequence of M+1 coefficients, and impulse response data (h_{BL})_{ω} composed of a sequence of N+1 coefficients are calculated.

Then, the impulse response data output section 21a supplies the foregoing impulse response data (h_{BH})_{ω} having the characteristic of the linear phase filter to the high frequency convolution arithmetic section of the designated channel, of the high frequency convolution arithmetic sections B1 to Bp. Thus, the coefficients of the multipliers KB₁, KB₂ to KB_{M+1} are set. The impulse response data output section 21a also supplies the foregoing impulse response data (h_{BL})_{ω} having the characteristic of the minimum phase filter to the low frequency convolution arithmetic section of the designated channel, of the low frequency convolution arithmetic sections C1 to Cp. Thus, the coefficients of the multipliers KC₁, KC₂ to KC_{N+1} are set.

[4] When a command for ordering that the high frequency convolution arithmetic section is a minimum phase filter and the low frequency convolution arithmetic section is a linear phase filter, in a combination of the high frequency convolution arithmetic section B1 to Bp and the low frequency convolution arithmetic section C1 to Cp in each channel is issued:

When the listener or the like issues such a command, the target characteristic decision section 23 divides an audible frequency band into a high frequency band BH and a low frequency band BL in accordance with target characteristics designated by the listener or the like.

Then, as described above, the target characteristic decision section 23 searches through the storage section 40. Reference data Ha(f) and Hb(f) of frequency spectrums having the characteristic of the linear and minimum phase filters is obtained from the reference data storage region MEMA, in accordance with a result of searching through the storage section 40. Otherwise, data BH(f) of a frequency spectrum having the characteristic of the minimum phase filter related to the high frequency band BH of the designated channel, and data BL(f) of a frequency spectrum having the characteristic of the linear phase filter related to the low frequency band BL are obtained from the operation data storage region MEMC.

The gain and phase characteristic of one of the obtained reference data Hb(f) and data BH(f) of the frequency spectrum having the characteristic of the minimum phase filter related to the high frequency band BH (that is, one of Hb(f) and BH(f) having the characteristic of the minimum phase filter) are adjusted in accordance with the target characteristic, to generate new data BH(f) representing a frequency spectrum in the high frequency band BH. The gain and phase characteristic of one of the obtained reference data Ha(f) and data BL(f) of the frequency spectrum having the characteristic of the linear phase filter related to the low frequency band BL (that is, one of Ha(f) and BL(f) having the characteristic of the linear phase filter) a readjusted in accordance with the target characteristic, to generate new data BL(f) representing a frequency spectrum in the low frequency band BL. Then, the target characteristic decision section 23 supplies the new data BH(f) related to the high frequency band BH and the new data BL(f) related to the low frequency band BL to the inverse Fourier transform arithmetic section 21c, and stores them in the operation data storage region MEMC.

Then, as in the case of the foregoing [1], [2], and [3], the inverse Fourier transform arithmetic section 21c performs an inverse Fourier transform on each of the data sets BH(f) and BL(f) of the frequency spectrums supplied from the target characteristic decision section 23, and the window function arithmetic section 21b multiplies results by window functions ω. Thus, impulse response data (h_{BH})_{ω} composed of a sequence of M+1 coefficients, and impulse response data (h_{BL})_{ω} composed of a sequence of N+1 coefficients are calculated.

Then, the impulse response data output section 21a supplies the foregoing impulse response data (h_{BH})_{ω} having the characteristic of the minimum phase filter to the high frequency convolution arithmetic section of the designated channel, of the high frequency convolution arithmetic sections B1 to Bp. Thus, the coefficients of the multipliers KB₁, KB₂ to KB_{M+1} are set. The impulse response data output section 21a also supplies the foregoing impulse response data (h_{BL})_{ω} having the characteristic of the linear phase filter to the low frequency convolution arithmetic section of the designated channel, of the low frequency convolution arithmetic sections C1 to Cp. Thus, the coefficients of the multipliers KC₁, KC₂ to KC_{N+1} are set.

The delay time control section 22 generates the delay time data d1 to dp and e1 to ep for setting the delay times τ11 to τ1p and τ2l to τ2p of the delay sections D1 to Dp and E1 to Ep, which are provided in the signal processing unit A1 to Ap of every channel.

In other words, as in the case of the delay time control section 22 shown in FIG. 1, the delay time control section 22 shown in FIG. 4 according to this example also carries out correction time calculation processing described in the foregoing <1> to <4>, in accordance with the type of filter (linear phase filter or minimum phase filter) designated with respect to the high frequency convolution arithmetic sections B1 to Bp and the low frequency convolution arithmetic sections C1 to Cp, and the designated channel. Accordingly, correction time and the like are adjusted, and hence the delay time data d1 to dp and e1 to ep for setting the delay times τ11 to τ1p and τ21 to τ2p of the delay sections D1 to Dp and E1 to Ep is generated.

Next, the configuration and function of the operation section 30 will be described with reference to FIGS. 6A to 6D.

As shown in FIG. 6A, the operation section 30 has the display section 31 and the operation panel section 32 which are controlled by the control unit 20. The operation panel section 32 is provided with a plurality of operation switches S1 to S12, and a so-called volume switch 13. From the operation switches S1 to S12, the listener or the like inputs desired target characteristics to the control unit 20. The volume switch S13 is to adjust the speaker volume according to the amount of rotation thereof.

Description will be given of the functions of the respective operation switches S1 to S12. Initially, the operation switch S1 is provided to designate either one of the linear phase filter and the minimum phase filter. The operation switch S1 can designate the linear phase filter and the minimum phase filter alternately each time the listener or the like presses it.

The operation switch S2 is provided to designate any one of the channel divider, the graphic equalizer, and the time alignment to be adjusted. The operation switch S2 can switch the designation among the channel divider, the graphic equalizer, and the time alignment by turns each time the listener or the like presses it.

The operation switch S3 is provided to designate each individual cutoff slope in the high frequency band BH and the low frequency band BL, which is designated by the listener or the like as a target characteristic. The cutoff slops include ones extending from the higher cutoff frequency and the lower cutoff frequency of the high frequency band BH, and ones extending from the higher cutoff frequency and the lower cutoff frequency of the low frequency band BL. The operation switch S3 can switch the designation among the cutoff slopes each time the listener or the like presses it.

The operation switch S4 is called a memory key. The memory key is provided to store the current characteristics into the history storage region MEMB described above. Here, the current characteristics are those set in the high frequency convolution arithmetic sections B1 to Bp, the low frequency convolution arithmetic sections C1 to Cp, and the delay sections D1 to Dp and E1 to Ep formed in the signal processing units A1 to Ap of all the channels.

When the listener or the like presses the operation switch S4 continuously for more than a predetermined time, the current characteristics mentioned above can be updated and stored into the history storage regions MEMB. Besides, when the operation switch S4 is pressed for a short time (so-called one-touch operation), it can direct the target characteristic decision section 23, the inverse Fourier transform arithmetic section 21c, the window function arithmetic section 12b, and the impulse response data output section 21a to reset the characteristics of the high frequency convolution arithmetic sections B1 to Bp, the low frequency convolution arithmetic sections C1 to Cp, and the delay sections D1 to Dp and E1 to Ep based on the characteristic data already stored in the history storage region MEMB.

Like the operation switch S4, the operation switch S5 is also a so-called memory key. Due to the provision of these two operation switches S4 and S5, two sets of characteristic settings can be stored into the history storage region MEMB and used for resetting.

The operation switch S6 is provided to start and end an adjustment input on the channel divider, the graphic equalizer, or the time alignment, and to confirm an input target characteristic. When the listener or the like presses the operation switch S6 once continuously for more than a predetermined time, an adjustment input on the channel divider, the graphic equalizer, or the time alignment is started. When the listener or the like presses the operation switch S6 twice at predetermined timing during the adjustment input on the channel divider, the graphic equalizer, or the time alignment, the mode for the adjustment input can be ended. Moreover, when the listener or the like inputs a desired target characteristic and then presses the operation switch S6 once for a short time (so-called one-touch operation), the target characteristic can be confirmed and supplied to the target characteristic decision section 23.

The operation switch S7 is provided to switch and designate the high frequency band BH and the low frequency band BL for the listener or the like to adjust. The operation switch S7 can switch and designate the high frequency band BH and the low frequency band BL alternately each time the listener or the like presses it.

The operation switch S8 is provided to designate a channel for the listener or the like to adjust. The operation switch S8 can switch the designation among the first to pth channels described above each time the listener or the like presses it.

The operation switches S9 and S10 are provided to switch and designate a narrow band in steps of ⅓ oct within the audible frequency band when the listener or the like adjusts the graphic equalizer. Each time the listener or the like presses the operation switch S9, the designated narrow band can be switched from lower to higher frequencies within the audible frequency band. Each time the listener or the like presses the operation switch S10, the designated narrow band can be switched from higher to lower frequencies within the audible frequency band.

The operation switch S11 is called a down key, and the operation switch S12 an up key. These keys are provided to input a specific target characteristic when the listener or the like adjusts the frequency division (channel divider), the graphic equalizer, and the time alignment. The details will be given later in conjunction with the description of operation. The listener or the like can operate the operation switches S11 and S12 as appropriate to make input operations such as fine designation of the bandwidths of the high frequency band BH and the low frequency band BL.

Next, the operation of the acoustic characteristic adjustment device 10 according to the present embodiment will be described with reference to FIGS. 6A to 6D and the flowcharts of FIGS. 7A to 7C. Incidentally, the following description will deal with the operations when the listener or the like actually operates the individual operation switches S1 to S12.

When the listener or the like presses the operation switch S6 for a predetermined time, the control unit 20 enters an operation mode for inputting a target characteristic. As the listener or the like operates the individual operation switches S1 to S12 subsequently, the control unit 20 makes the following operations.

Suppose, initially, that the listener or the like holds down the operation switch S2. According to the instruction of the control unit 20, the display section 31 shows an adjustment input mode display of the channel divider shown in FIG. 6B, an adjustment input mode display of the graphic equalizer shown in FIG. 6C, and an adjustment input mode display of the time alignment shown in FIG. 6D by turns at predetermined time intervals.

Here, if the listener or the like releases the operation switch S2 during the display shown in FIG. 6B, an adjustment input mode of the channel divider shown in FIG. 7A is started under the control of the control unit 20. If the operation switch S2 is released during the display shown in FIG. 6C, an adjustment input mode of the graphic equalizer shown in FIG. 7B is started under the control of the control unit 20. If the operation switch S2 is released during the display shown in FIG. 6D, an adjustment input mode of the time alignment shown in FIG. 7C is started under the control of the control unit 20.

[Operation in Adjustment Input Mode of Channel Divider]

When the adjustment input mode of the channel divider is started, at step ST10, curves indicating the high frequency band BH and the low frequency band BL are displayed as shown in FIG. 6B.

Next, at step ST11, the listener or the like operates the operation switch S11 or S12 as appropriate to set a desired channel. When a one-touch operation is made on the operation switch S6, the target characteristic decision section 23 inputs the data indicating the designated channel.

When the listener or the like presses the operation switch S7 as appropriate after the foregoing channel designation, the curve of the high frequency band BH and the curve of the low frequency band BL are blinked alternately. If the listener or the like releases the operation switch S7 while the reference curve showing the gain characteristic of the high frequency band BH is blinked, the adjustment to the high frequency band BH is started. If the operation switch S7 is released while the reference curve showing the gain characteristic of the low frequency band BL is blinked, the adjustment to the low frequency band BL is started.

Suppose that the listener or the like operates the operation switch S3 after the selection of the high frequency band BH. The lower cutoff frequency and the higher cutoff frequency of the high frequency band BH are selected alternately upon each operation. If the higher cutoff frequency is selected, the operation switches S11 and S12 are operated as appropriate to adjust the higher cutoff frequency up and down. Then, when a one-touch operation is made on the operation switch S6, the target characteristic decision section 23 inputs the data on the higher cutoff frequency of the high frequency band BH. If the lower cutoff frequency is selected, the operation switches S11 and S12 are operated as appropriate to adjust the lower cutoff frequency up and down. Then, when a one-touch operation is made on the operation switch S6, the target characteristic decision section 23 inputs the data on the lower cutoff frequency of the high frequency band BH.

Suppose that the listener or the like operates the operation switch S3 after the selection of the low frequency band BL. The lower cutoff frequency and the higher cutoff frequency of the low frequency band BL are designated alternately upon each operation. If the higher cutoff frequency is selected, the operation switches S11 and S12 are operated as appropriate to adjust the higher cutoff frequency up and down. Then, when a one-touch operation is made on the operation switch S6, the target characteristic decision section 23 inputs the data on the higher cutoff frequency of the low frequency band BL. If the lower cutoff frequency is selected, the operation switches S11 and S12 are operated as appropriate to adjust the lower cutoff frequency up and down. Then, when a one-touch operation is made on the operation switch S6, the target characteristic decision section 23 inputs the data on the lower cutoff frequency of the low frequency band BL.

In this way, the listener or the like can operate the operation switches S7, S11, S12, and S6 as appropriate to designate the higher cutoff frequency and lower cutoff frequency of either of the high frequency band BH and low frequency band BL, and further specify the bandwidths of the respective bands BH and BL.

Next, the control unit 20 moves to the processing of step ST12. Suppose here that the listener or the like operates the operation switch S7 as appropriate to select the high frequency band BH, and then operates the operation switch S1 to select and designate the linear phase filter or the minimum phase filter. When a one-touch operation is made on the operation switch S6, the target characteristic decision section 23 inputs the data indicating the type of the filter of the high frequency band BH (the linear phase filter or the minimum phase filter). Suppose, on the other hand, that the listener or the like operates the operation switch S7 as appropriate to select the low frequency band BL, and then operates the operation switch S1 to select and designate the linear phase filter or the minimum phase filter. When a one-touch operation is made on the operation switch S6, the target characteristic decision section 23 inputs the data indicating the type of the filter of the low frequency band BL (the linear phase filter or the minimum phase filter).

Next, the control unit 20 moves to the processing of step ST13. Suppose here that the listener or the like operates the operation switch S3 as appropriate. Then, curves q1 to q4 indicating the cutoff slopes of the high frequency band BH and the low frequency band BL, respectively, are blinked by turns.

If the listener or the like releases the operation switch S3 while the cutoff slope curve q1 is blinked, and operates the operation switches S11 and S12 as appropriate, the displayed curve q1 varies in inclination. Depending on the inclination of the curve q1, the amount of attenuation of the cutoff slope can be adjusted up and down within the range of through (0 dB) and the maximum, or −72 dB/oct, in steps of −6 dB/oct. When the listener or the like makes a one-touch operation on the operation switch S6 for confirmation, the target characteristic decision section 23 inputs the data indicating the amount of attenuation of the cutoff slope corresponding to the inclination of the curve q1.

Similarly, when the listener or the like operates the operation switches S3, S11, S12, and S6 to change and confirm the inclinations of the remaining curves q2 to q4, the target characteristic decision section 23 inputs the data indicating the amounts of attenuation of the cutoff slopes corresponding to the inclinations of those curves q2 to q4.

Next, when the listener or the like operates the operation switch S6 twice, the control unit 20 ends the adjustment input mode of the channel divider.

Subsequently, based on the data on the target characteristic concerning the channel divider input so far, the target characteristic decision section 23 edits the data on the frequency spectrum stored in the reference data storage region MEMA or the history storage region MEMB as described above. The target characteristic decision section 23 also supplies the data BH(f) and BL(f) on the frequency spectrum created newly to the inverse Fourier transform arithmetic section 21c, and stores the same into the reference data storage region MEMA. The inverse Fourier transform arithmetic section 21c and the window function arithmetic section 12b creates new impulse response data (h_{BH})_{ω}(h_{BL})_{ω} from the data BH(f) and BL(f). The impulse response data output section 21a supplies the impulse response data (h_{BH})_{ω}(h_{BL})_{ω} to the high frequency convolution arithmetic section and the low frequency convolution arithmetic section of the designated channel. As a result, the acoustic characteristic of the channel is updated.

Moreover, based on the types of the filters of the high frequency convolution arithmetic section and the low frequency convolution arithmetic section designated at the foregoing step ST12 (the linear phase filters or the minimum phase filters), the delay time control section 22 performs the same processing as any of the processing <1> to <4> described in the foregoing embodiment selectively. As a result, data on new correction times is created. By using the data on the new correction times, the delay time control section 22 also adjusts the correction times of the delay times that are set in the delay sections formed in the signal processing unit of the designated channel. The output signals output from the high frequency convolution arithmetic section and the low frequency arithmetic convolution section are thus matched in phase.

Suppose, for example, that the designated channel is the first channel, and the delay time τ11 set in the delay section D1 is (T11+ΔT11). Then, the delay time control section 22 adjusts the delay section D1 by using the delay time τ11 which is the sum of the alignment time T11 and the new correction time calculated as above.

[Operation in Adjustment Input Mode of Graphic Equalizer]

Suppose that the listener or the like presses the operation switch S6 for a predetermined time as described above, thereby setting the control unit 20 to the operation mode for inputting a target characteristic. Then, the operation switch S2 is operated as appropriate to start the adjustment input mode of the graphic equalizer shown in FIG. 7B.

Initially, at step ST20, the frequency-gain characteristic showing reference gains for respective narrow bands in steps of ⅓ oct is displayed in the form of a bar chart as shown in FIG. 6C.

Next, the control unit 20 moves to the processing of step ST21. Suppose here that the listener or the like operates the operation switches S9 and S10 as appropriate. Each time the operation switch S9 is operated, the blinking on the foregoing bar chart shifts from lower to higher frequencies. Each time the operation switch S10 is pressed, the blinking on the foregoing bar chart shifts from higher to lower frequencies.

When the listener or the like stops operating the operation switches S9 and S10, and then operates the operation switches S11 and S12 as appropriate, the length of the bar blinked on the display section 31 is changed on-screen. Next, the listener or the like makes a one-touch operation on the operation switch S6, so that the target characteristic decision section 23 inputs the data indicating the amount of boost or the amount of cut proportionate to the length of the bar.

The listener or the like can also repeat operating the operation switches S9, S10, S11, and S12 in the same manner, whereby other desired bars are switched into blinking and changed in length. When the listener or the like makes a one-touch operation on the operation switch S6, the target characteristic decision section 23 inputs the data indicating the amounts of boost or the amounts of cut proportionate to the lengths of the remaining bars.

Next, when the listener or the like operates the operation switch S6 twice, the target characteristic decision section 23 inputs data that gives the amount of boost or the amount of cut of 0 dB to the rest of the narrow bands as to which the listener or the like has made no input. Then, the control unit 20 ends the adjustment input mode of the graphic equalizer.

Subsequently, based on the data indicating the amounts of boost or the amounts of cut of the narrow bands input by the listener or the like and the data on the rest of the narrow bands (0-dB data), i.e., based on the amounts of boost or the amounts of cut of the entire audible frequency band, the target characteristic decision section 23 edits the data on the frequency spectrum stored in the reference data storage region MEMA or the history storage region MEMB as described above. The target characteristic decision section 23 also supplies the data BH(f) and BL(f) on the frequency spectrum created newly to the inverse Fourier transform arithmetic section 21c, and stores the same into the reference data storage region MEMA. The inverse Fourier transform arithmetic section 21c and the window function arithmetic section 12b creates new impulse response data (h_{BH})_{ω}(h_{BL})_{ω} from the data BH(f) and BL(f). The impulse response data output section 21a supplies the impulse response data (h_{BH})_{ω}(h_{BL})_{ω} to the high frequency convolution arithmetic section and the low frequency convolution arithmetic section of the designated channel. As a result, the acoustic characteristic of the channel is updated.

[Operation in Adjustment Input Mode of Time Alignment]

As described above, the listener or the like presses the operation switch S6 for a predetermined time to set the control unit 20 to the operation mode for inputting a target characteristic. Then, the operation switch S2 is operated as appropriate to start the adjustment input mode of the graphic equalizer shown in FIG. 7C.

Initially, at step ST30, a table for inputting the distances from the speakers to the listening position or the like channel by channel is displayed as shown in FIG. 6D.

The “Hi” fields of the respective channels are ones for inputting the distances from the speakers connected to the routes of the delay sections D1 to Dp to the listening position or the like, respectively. The “LOW” fields of the respective channels are ones for inputting the distances from the speakers connected to the routes of the delay sections E1 to Ep to the listening position or the like, respectively.

Next, the control unit 20 moves to the processing of step ST31. Here, when the listener or the like operates the operation switch S7 as appropriate, the fields showing “**** cm” in FIG. 6D are inverted in color by turns from the top to the bottom. When the listener or the like operates the operation switch S8 as appropriate, the foregoing fields showing “**** cm” are inverted in color by turns from the bottom to the top. For example, the text color of “**** cm” is highlighted from black to gray.

When the listener or the like switches a desired field into highlight and then holds down the operation switch S11 or S12 for an appropriate time, the numeric value in the highlighted field is changed on-screen. Then, when the listener or the like makes a one-touch operation on the operation switch S6, the target characteristic decision section 23 inputs the numeric value in the highlighted field as the data indicating the distance (in units of cm) from the speaker to the listening position or the like.

The listener or the like can also operate the operation switches S7, S8, S11, and S12 in the same manner, thereby highlighting other fields and inputting numeric values indicating the distances from the speakers to the listening position or the like. Then, a one-touch operation is made on the operation switch S6, so that the target characteristic decision section 23 can input the data indicating the distances from the speakers to the listening position or the like.

When the listener or the like operates the operation switch S6 twice, the control unit 20 ends the adjustment input mode of the time alignment.

Subsequently, the delay time control section 22 calculates new alignment times for each channel based on the foregoing distance data input by the target characteristic decision section 23. The alignment times excluding the correction times set in the delay sections of the designated channel are adjusted by using the new alignment times described above. The output signals output from the high frequency convolution arithmetic sections and the low frequency convolution arithmetic sections are thus matched in phase.

Suppose, for example, that the designated channel is the first channel, and the delay time τ11 set in the delay section D1 is (T11+ΔT11). Then, the delay time control section 22 adjusts the delay section D1 by using the delay time τ11 which is the sum of the foregoing new alignment time calculated and the correction time ΔT11.

As described above, the acoustic characteristic adjustment device 10 of the present embodiment has the operation section 30 for performing adjustment inputs on the channel divider, the graphic equalizer, and the time alignment. The listener or the like can operate the operation section 30 to conduct the individual adjustment inputs separately with precision. It is therefore possible to provide a high level of satisfaction and a high degree of flexibility to the listener or the like, along with excellent operability.

When the listener or the like performs the adjustment inputs on the channel divider, the graphic equalizer, and the time alignment, the control unit 20 adjusts the characteristics, including the gain characteristics, phase characteristics, and delay characteristics, of the signal processing units A1 to Ap of the respective channels automatically based on the input target characteristics data. It is therefore possible to provide excellent operability and the like to the listener or the like.

Moreover, when the acoustic characteristic adjustment device 10 of the present embodiment is applied to audiovisual equipment or the like for reproducing images and sounds, the listener or the like can set both the high frequency convolution arithmetic sections B1 to Bp and the low frequency convolution arithmetic sections C1 to Cp in the signal processing units A1 to Ap to the minimum phase filters. This eliminates the time delays during the convolution arithmetics in the high frequency convolution arithmetic sections B1 to Bp and the low frequency convolution arithmetic sections C1 to Cp. It is therefore possible to make sounds matching with images displayed on a display or the like occur in the listening position (or watching position). In other words, it is possible to make sounds having acoustic characteristics matching with images occur in the listening position (or watching position).

In addition, the sampling numbers (M+1) of the respective pieces of impulse response data h1m to hpm are made smaller than the sampling numbers (N+1) of the respective pieces of impulse response data h1n to hpn. Based on these pieces of impulse response data h1m to hpm and h1n to hpn, the high frequency convolution arithmetic sections B1 to Bp and the low frequency convolution arithmetic sections C1 to Cp perform their respective convolution arithmetics. It is therefore possible to reduce the total amount of the impulse response data h1m to hpm and h1n to hpn necessary for performing the convolution arithmetics, and achieve miniaturization and the like of the signal processing units A1 to Ap.

Incidentally, the configuration and operation method of the operation section 30 described with reference to FIGS. 6A to 6D are just a specific example. The operation section 30 may have any other configuration and other operation method as long as the same functions as those described with reference to the flowcharts of FIGS. 7A to 7C are available.

The present embodiment has dealt with the case where the data on the frequency spectrum is stored in the storage section 40 as shown in FIG. 4. Here, the control unit 20 edits the data so as to match with the target characteristic, and performs inverse Fourier transforms, thereby working out the impulse response data to be supplied to the individual high frequency convolution arithmetic sections and low frequency convolution arithmetic sections. Nevertheless, instead of the data on the frequency spectrum, the impulse response data to be supplied to the individual high frequency convolution arithmetic sections and low frequency convolution arithmetic sections may be stored into the storage section 40 in advance. According to this configuration, the storage section 40 requires a greater storage capacity. It is possible, however, to reduce the processing for performing inverse Fourier transforms and window function arithmetics. It is also possible to omit the inverse Fourier transform arithmetic section 21c and the window function arithmetic section 21b.

While there has been described what are at present considered to be preferred embodiments of the present invention, it will be understood that various modifications may be made thereto, and it is intended that the appended claims cover all such modifications as fall within the true spirit and scope of the invention.

1. An acoustic characteristic adjustment device comprising:
signal processing means, provided in each of one or a plurality of channels, for adjusting the acoustic characteristic of sound emitted from a speaker of each channel in a listening position or the like, the signal processing means of each channel including convolution arithmetic means for carrying out frequency division and the adjustment of gain and phase characteristic with respect to a signal component of an input audio signal in one or a plurality of frequency bands by convolution arithmetic, and delay means for delaying an output signal from the convolution arithmetic means to output the output signal to the speaker;
operation means for allowing selectively inputting target characteristic at least representing the characteristic of the one or plurality of frequency bands of each channel, the gain and phase characteristic, and a distance from each speaker to the listening position or the like;
impulse characteristic control means for generating impulse response data of the one or plurality of frequency bands of each channel on the basis of the target characteristic input from the operation means, the impulse characteristic data representing an impulse response for use in performing the convolution arithmetic with the input audio signal in the convolution arithmetic means; and
delay time control means for calculating each alignment time which sound needs for traveling each distance, and a correction time for compensating difference in output time output from the convolution arithmetic means, and for calculating delay time by correcting each alignment time with the correction time to adjust the delay time of the delay means with the calculated delay time.

2. The acoustic characteristic adjustment device according to claim 1, wherein
the number of taps of the convolution arithmetic means is reduced with increase in frequency of the one or plurality of frequency bands.

3. The acoustic characteristic adjustment device according to claim 1, wherein
the operation means comprises input means for variably setting at least the target characteristic of the one or plurality of frequency bands of each channel.

4. The acoustic characteristic adjustment device according to claim 1, wherein:
the operation means comprises input means for integrally or separately inputting at least the type of filter which is realized in the convolution arithmetic means of each channel by the convolution arithmetic;
the impulse characteristic control means generates at least the impulse response data representing the impulse response of the convolution arithmetic means of each channel, on the basis of the characteristic of the input type of filter and the target characteristic; and
the delay time control means calculates the correction time in accordance with at least the difference in output time according to the characteristic of each filter realized by the convolution arithmetic means of each channel.

5. The acoustic characteristic adjustment device according to claim 1, wherein:
the operation means comprises input means for integrally or incrementally inputting and changing at least the type of filter realized in the convolution arithmetic means of each channel by the convolution arithmetic, while at least the variable setup of the target characteristic of the one or plurality of frequency bands of every channel is maintained;
the impulse characteristic control means generates at least the impulse response data representing the impulse response of the convolution arithmetic means of each channel on the basis of the characteristic of the changed and input type of filter and target characteristic; and
the delay time control means calculates the correction time in accordance with at least the difference in output time according to the characteristic of each filter realized by the convolution arithmetic means of each channel.

6. The acoustic characteristic adjustment device according to claim 4 or 5, further comprising storage means for storing at least the characteristic of a linear phase filter and the characteristic of a minimum phase filter in advance, as the characteristic of the input type of filter.

7. The acoustic characteristic adjustment device according to claim 6, wherein
each of the characteristic of the linear phase filter and the characteristic of the minimum phase filter is composed of the data of a frequency spectrum.

8. The acoustic characteristic adjustment device according to claim 4 or 5, wherein
the impulse characteristic control means comprises
target characteristic decision means for editing the data of the frequency spectrum corresponding to the type of filter input from the operation means on the basis of the target characteristic, and
inverse Fourier transform arithmetic means for performing an inverse Fourier transform on the data of the frequency spectrum edited by the target characteristic decision means to calculate the impulse response data.

9. The acoustic characteristic adjustment device stated according to claim 4 or 5, wherein
the impulse characteristic control means comprises
inverse Fourier transform arithmetic means for performing an inverse Fourier transform on the data of the frequency spectrum edited by the target characteristic decision means, and
window function arithmetic means for calculating a window function on the output of the inverse Fourier transform arithmetic means to generate the impulse response data.
